(19) United States
(12) Patent Application Publication
(10) Pub. No.: US 2026/0076252 A1
(43) Pub. Date: Mar. 12, 2026

(54) Power Semiconductor Device Package

(71) Applicant: Wolfspeed, Inc., Durham, NC (US)

(72) Inventors: Adil Salman, Morrisville, NC (US); Geza Dezsi, Durham, NC (US)

(21) Appl. No.: 18/882,003

(22) Filed: Sep. 11, 2024

(51) Int. Cl. H01L 23/04; H01L 23/31; H01L 23/49; H01L 23/52; H01L 25/07; H01L 29/16; H01L 29/20; H01L 29/78; H01L 29/872

(52) U.S. Cl. CPC H10W 76/12; H10W 72/00; H10W 72/50; H10W 90/00; H10D 8/60; H10D 30/60; H10D 62/8325; H10D 62/8503; H10W 74/111

(57) ABSTRACT

Power semiconductor device packages are provided. In one example, a power semiconductor device package includes a housing, a first semiconductor die and a second semiconductor die, and a plurality of electrical leads extending from the housing. At least one electrical lead of the plurality of electrical leads may be coupled to each of the first semiconductor die and the second semiconductor die. The second semiconductor die may be a different type of semiconductor device relative to the first semiconductor die. In one example, the power semiconductor device package includes a creepage cutout in the housing that provides a creepage distance between at least two electrical leads of the plurality of electrical leads.

### FIELD

The present disclosure relates generally to semiconductor devices.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices. Example semiconductor devices may be power modules, which may include one or more power devices and other circuit components and can be used, for instance, to dynamically switch large amounts of power through various components, such as motors, inverters, generators, and the like. These semiconductor devices may be fabricated from wide bandgap semiconductor materials, such as silicon carbide (“SiC”) and/or Group III nitride-based semiconductor materials.

### SUMMARY

Aspects and advantages of embodiments of the present disclosure will be set forth in part in the following description, or can be learned from the description, or can be learned through practice of the embodiments.

One example aspect of the present disclosure is directed to a discrete power semiconductor device package. The discrete power semiconductor device package includes a housing. The discrete power semiconductor device package includes a first semiconductor die and a second semiconductor die. The first semiconductor die is a different type of semiconductor device relative to the second semiconductor die. The power semiconductor device package includes a plurality of electrical leads extending from the housing. At least one electrical lead of the plurality of electrical leads is coupled to each of the first semiconductor die and the second semiconductor die.

Another example aspect of the present disclosure is directed to a power semiconductor device package. The power semiconductor device package includes a housing, a first semiconductor die and a second semiconductor die, a plurality of electrical leads extending from the housing, and at least two creepage cutouts in the housing.

Another examples aspect of the present disclosure is directed to a power semiconductor device package. The power semiconductor device package includes a housing. The power semiconductor device package includes a first semiconductor die in the housing. The first semiconductor die includes a Schottky diode. The power semiconductor device package includes a second semiconductor die in the housing. The second semiconductor die includes a metal-oxide-semiconductor field-effect transistor (MOSFET). The power semiconductor device package includes a plurality of electrical leads extending from the housing. The plurality of electrical leads includes a first lead coupled to a cathode contact of the first semiconductor die, a second lead coupled to an anode contact of the first semiconductor die and a drain contact of the second semiconductor die, and a third lead coupled to a source contact of the second semiconductor die.

Another example aspect of the present disclosure is directed to a power semiconductor device package. The power semiconductor device package includes a housing. The power semiconductor device package includes a first semiconductor die and a second semiconductor die that is a different type of semiconductor device relative to the first semiconductor die. The power semiconductor device package includes a plurality of electrical leads extending from the housing. The plurality of electrical leads includes a first lead coupled to the first semiconductor die, a second lead coupled to the first semiconductor die and the second semiconductor die, and a third lead coupled to the second semiconductor die. The power semiconductor device package includes a first creepage cutout in the housing. The first creepage cutout is between the first lead and the second lead. The power semiconductor device package includes a second creepage cutout in the housing. The second creepage cutout is between the second lead and the third lead.

Another example aspect of the present disclosure is directed to a power semiconductor device package. The power semiconductor device package includes a housing. The power semiconductor device package includes a first semiconductor die and a second semiconductor die that is different from the first semiconductor die. The power semiconductor device package includes a plurality of electrical leads extending from the housing. The power semiconductor device package includes a thermal pad that is electrically isolated from the plurality of electrical leads. The power semiconductor device package includes a creepage cutout in the housing, the creepage cutout providing a creepage distance between at least two electrical leads of the plurality of electrical leads. The power semiconductor device package includes a creepage feature on the housing, the creepage feature providing a creepage distance between the thermal pad and the plurality of electrical leads.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a top perspective view of an example power semiconductor device package according to example embodiments of the present disclosure;

FIG. 2 depicts a bottom perspective view of the example power semiconductor device package of FIG. 1 according to example embodiments of the present disclosure;

FIG. 3 depicts a circuit schematic of the example power semiconductor device package of FIG. 1 according to example embodiments of the present disclosure;

FIG. 4A depicts a top perspective wireframe view of an example power semiconductor device package according to example embodiments of the present disclosure;

FIG. 4B depicts a top wireframe view of the example power semiconductor device package of FIG. 4A according to example embodiments of the present disclosure;

FIG. 5 depicts a close perspective view of an example creepage feature of an example power semiconductor device package according to example embodiments of the present disclosure;

FIG. 6 depicts a close perspective view of example creepage cutouts of an example power semiconductor device package according to example embodiments of the present disclosure;

FIG. 7 depicts a side plan view of an example creepage feature of an example power semiconductor device package according to example embodiments of the present disclosure;

FIG. 8A depicts a top perspective wireframe view of an example power semiconductor device package according to example embodiments of the present disclosure;

FIG. 8B depicts a top wireframe view of the example power semiconductor device package of FIG. 8A according to example embodiments of the present disclosure;

FIG. 9A depicts a bottom perspective view of an example power semiconductor device package according to example embodiments of the present disclosure;

FIG. 9B depicts a bottom perspective wireframe view of the example power semiconductor device package of FIG. 9A according to example embodiments of the present disclosure;

FIG. 9C depicts a bottom perspective wireframe view of the example power semiconductor device package of FIG. 9A according to example embodiments of the present disclosure;

FIG. 10 depicts a top perspective view of an example power semiconductor device package according to example embodiments of the present disclosure;

FIG. 11 depicts a bottom perspective view of the example power semiconductor device package of FIG. 10 according to example embodiments of the present disclosure;

FIG. 12 depicts a top perspective wireframe view of the example power semiconductor device package of FIG. 10 according to example embodiments of the present disclosure;

FIG. 13A-13G depict perspective views of example creepage cutouts of an example power semiconductor device package according to example embodiments of the present disclosure; and

FIG. 14 depicts a close perspective view of an example power semiconductor device package according to example embodiments of the present disclosure.

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Semiconductor device packages, such as power semiconductor device packages (e.g., discrete power semiconductor device packages, power modules, etc.), have been developed that include a semiconductor die. In some examples, such semiconductor die include one or more semiconductor devices, such as a metal-oxide-semiconductor field-effect transistor (MOSFET), a Schottky diode, and/or a high electron mobility transistor (HEMT) device. Power semiconductor device packages with MOSFETs may be employed in a variety of applications to enable higher switching frequencies along with reduced associated losses, higher blocking voltages, and improved avalanche capabilities. Example applications may include high performance industrial power supplies, server/telecom power, electric vehicle charging systems, energy storage systems, uninterruptible power supplies, high-voltage DC/DC converters, electric vehicles, and battery management systems. Power semiconductor device packages with Schottky diodes and/or HEMT devices may be employed in many of the same high-performance power applications described above with respect to MOSFETs. In some examples, power semiconductor device packages with Schottky diodes may be employed in systems that also include power semiconductor device packages with MOSFETs.

Example aspects of the present disclosure are directed to power semiconductor device packages (e.g., discrete power semiconductor device packages, power modules, etc.) for use in semiconductor applications and other electronic applications. It should be understood that the terms “semiconductor device package,” “semiconductor package,” “power semiconductor device package,” and/or “power semiconductor package” may be used interchangeably. In some examples, semiconductor device packages may include one or more semiconductor die. The one or more semiconductor die may include a wide bandgap semiconductor material. A wide bandgap semiconductor has a band gap greater than about 1.40 eV, such as silicon carbide (SiC) and/or a Group-III nitride (e.g., gallium nitride).

In some examples, the one or more semiconductor die may include one or more semiconductor devices, such as transistors, diodes, and/or thyristors. For instance, in some examples, the one or more semiconductor die may include a metal-oxide-semiconductor field-effect transistor (MOSFET), such as a silicon carbide-based MOSFET. In such examples, the MOSFET(s) may be located between a first (e.g., source) lead and a second (e.g., drain) lead of a power semiconductor device package to form, for instance, a vertical structure power semiconductor device. Additionally and/or alternatively, in some examples, the one or more semiconductor die may include a Schottky diode, such as a silicon carbide-based Schottky diode. In such examples, the Schottky diode(s) may be located between a first (e.g., cathode) lead and a second (e.g., anode) lead of a power semiconductor device package to form, for instance, a vertical structure power semiconductor device. Additionally and/or alternatively, in some examples, the one or more semiconductor die may include a HEMT device, such as a Group-III nitride-based HEMT device.

It should be understood that aspects of the present disclosure are discussed with reference to silicon carbide-based MOSFET devices and silicon carbide-based Schottky diode devices for purposes of illustration and discussion. Those having ordinary skill in the art, using the disclosures provided herein, will understand that the power semiconductor device packages of the present disclosure may include other power semiconductor devices without deviating from the scope of the present disclosure, such as, by way of non-limiting example, diodes (e.g., PiN diodes, etc.), insulated gate bipolar transistors, HEMTs, and/or other devices. Furthermore, it should be understood that aspects of the present disclosure are discussed with reference to vertical structure power semiconductor devices for purposes of illustration and discussion. Those having ordinary skill in the art, using the disclosures provided herein, will understand that power semiconductor device packages of the present disclosure may include other forms of power semiconductor devices without deviating from the scope of the present disclosure, such as, by way of non-limiting example, horizontal structure power semiconductor devices and/or the like.

In some power semiconductor device packages, the one or more semiconductor die may be attached to a submount, such as a lead frame and/or a power substrate (e.g., direct bonded copper (DBC) substrate, active metal brazed (AMB) substrate, etc.), by a die-attach material between the one or more semiconductor die and the submount. For instance, in some examples, a die-attach material may be deposited on the submount, and the semiconductor die (or other component) may be placed on the die-attach material, and the die-attach material may be subjected to bonding or a bonding process (e.g., sintering) to secure the semiconductor die (or other component) to the die-attach material. Various types of die-attach material may be used to bond the one or more semiconductor die to the submount such as, for instance, metal sintering die-attach (e.g., silver (Ag) or copper (Cu)) and conductive adhesive die-attach. Additionally and/or alternatively, in some examples, the power semiconductor device package may use wire bond(s) (e.g., aluminum wire bond(s)) for interconnection between portions of the one or more semiconductor die (e.g., a gate contact) and the package (e.g., lead frame). Furthermore, in some examples, a passivation layer may be provided on the one or more semiconductor die, such as a silicon nitride and/or polyimide passivation layer.

The power semiconductor device package may further include a housing in which the one or more semiconductor die may be arranged. More particularly, in some examples, the housing may be and/or may include an encapsulating material (e.g., epoxy mold compound (EMC)) formed around at least a portion of the submount and the one or more semiconductor die. Hence, in some examples, the power semiconductor device package may be a discrete power semiconductor device package. The power semiconductor device package may also include one or more electrical leads extending from the housing. In some examples, the power semiconductor device package may include a plurality of electrical leads, each of which extending from a same side of the housing relative to one another. In other examples, the power semiconductor device package may include a plurality of electrical leads, at least one of which extending from a different side of the housing relative to the other electrical leads. It should be understood that, as used herein, a “plurality of electrical leads” includes at least two, or more, electrical leads extending from the housing.

As used herein, a “discrete power semiconductor device package” refers to a power semiconductor device package having a housing (e.g., encapsulating material) that is molded directly onto a submount, such as a lead frame, with one or more semiconductor die attached thereto. As used herein, a “power module” refers to a power semiconductor device package having a plurality of electrically interconnected semiconductor die arranged on one or more power substrates, such as direct bonded copper (DBC) substrates and/or active metal brazed (AMB) substrates.

The power semiconductor device package may further include one or more metallization structures. A “metallization structure” is any layer, structure, or other portion of a semiconductor die that incorporates a metal for thermal and/or electrical conduction. Metallization structures in a semiconductor device may be used, for instance, to provide an electrically conductive and/or thermally conductive connection to the one or more semiconductor die. The metallization structure may include, for instance, one or more electrodes, contacts, interconnections, bonding pads, backside layers, metal layers, or metal coatings of the semiconductor device on the semiconductor die.

Packaging technology for semiconductor devices plays an important role in defining the performance of the semiconductor devices. For example, the packaging of a power semiconductor device package may limit the ability of the one or more semiconductor die to dissipate heat, conduct current, or even switch at particular speeds (e.g., due to stray inductance). Ineffective heat dissipation can create problems for semiconductor devices (e.g., small form factor semiconductor devices) or in situations where the semiconductor device comes into close contact with the housing. Excessive heat can adversely impact the operation of the semiconductor device itself, as well as the electronic system that uses that semiconductor device.

The packaging of a power semiconductor die may also affect clearance and creepage of the semiconductor device. More particularly, clearance (or “clearance distance”) is the shortest direct path through air between conductors at different voltage potentials. Adequate clearance distances are vital to preventing an ionization of an air gap of the semiconductor device because a breakdown along a clearance path can happen instantaneously under certain operating conditions.

Similarly, creepage (or “creepage distance”) is the shortest direct path along a surface between conductors at different voltage potentials. As such, the packaging of the power semiconductor device plays an important role in determining the creepage distance of the power semiconductor device. Creepage may occur in situations where charge carriers are influenced by, for instance, electric fields, temperature gradients, and/or other factors that cause the charge carriers to drift along the surface of the power semiconductor device. Depending on the packaging and operating conditions of the power semiconductor device, creepage may contribute to leakage currents and/or other non-ideal behaviors in the semiconductor device. Thus, creepage distances are an important design consideration to ensure proper insulation and to prevent electrical breakdown, especially in high-voltage applications that require increased creepage distances.

Accordingly, to reduce the adverse performance-related effects associated with packaging and to increase one or more operating characteristics of the power semiconductor device package (e.g., operating voltage, rated current, etc.), example aspects of the present disclosure are directed to power semiconductor device packages having a housing, a plurality of semiconductor die on a submount, and a plurality of electrical leads extending from the housing. Furthermore, the power semiconductor device package of the present disclosure may further include one or more creepage extension structures (e.g., creepage cutouts, creepage features, etc.) in the housing. As will be discussed in greater detail below, the creepage extension structure(s) may provide the power semiconductor device package with increased creepage distance(s), thereby reducing the adverse performance-related effects discussed above and increasing the current and voltage handling capabilities of the power semiconductor device package.

More particularly, a power semiconductor device package of the present disclosure may include a housing that, in some examples, includes an encapsulating material (e.g., epoxy mold compound (EMC)). In some examples, the housing may have a plurality of surfaces and/or a plurality of sides. For instance, the housing may include one or more “major” sides and one or more “minor” sides. As used herein, a “major side(s)” and/or a “major surface(s)” refers to a primary (e.g., most significant) surface(s) of the housing, such as the principal face(s) of the housing, the side(s) having the largest surface area, and/or the like. Conversely, a “minor side(s)” and/or a “minor surface(s)” refers to a secondary (e.g., less prominent) surface(s) of the housing relative to the “major side(s),” such as the side surface(s) of the housing, the side(s) having a smaller surface area relative to the principal faces, and/or the like. It should be understood that, when describing the housing, the terms “surface” and “side” may be used interchangeably.

More particularly, the housing may include a first major side (e.g., front side) and a second major side (e.g., back side, rear side, etc.) that is generally opposite the first major side. The first major side and the second major side may be generally parallel relative to one another. The housing may further include one or more minor sides extending between the first major side and the second major side. For instance, in some examples, the housing may include a first minor side (e.g., bottom-side surface) and a second minor side (e.g., top-side surface) that is generally opposite the first minor side. The first minor side and the second minor side may be generally perpendicular to the first major side and the second major side. The first minor side and the second minor side may be generally parallel relative to one another. The housing may further include a third minor side (e.g., right-side surface) and a fourth minor side (e.g., left-side surface) opposite the third minor side. The third minor side and the fourth minor side may be generally perpendicular to the first major side and the second major side; likewise, the third minor side and the fourth minor side may be perpendicular to the first minor side and the second minor side. The third minor side and the fourth minor side may be generally parallel relative to one another.

In some examples, the power semiconductor device package of the present disclosure may include a through hole in the housing. More particularly, a power semiconductor device package of the present disclosure may include a through hole in the housing that extends through the housing from a first major side of the housing to a second major side of the housing. As such, the power semiconductor device package may be operable to receive a mounting screw through the through hole. In some examples, the through hole may be a circular through hole. In other examples, the through hole may be a non-circular through hole. Those having ordinary skill in the art, using the disclosures provided herein, will understand that the through hole may be any suitable shape without deviating from the scope of the present disclosure.

The power semiconductor device package of the present disclosure may include a plurality of semiconductor die at least partially within the housing. More particularly, the power semiconductor device package may include a first semiconductor die and a second semiconductor die arranged at least partially within the housing. As will be discussed in greater detail below, the first semiconductor die may be a different type of semiconductor device relative to the second semiconductor die. For instance, in some examples, the first semiconductor die may include a Schottky diode (e.g., silicon carbide-based Schottky diode, etc.), and the second semiconductor die may include a metal-oxide-semiconductor field-effect transistor (MOSFET) (e.g., silicon carbide-based MOSFET, etc.). In some examples, the power semiconductor device package may further include a third semiconductor die arranged at least partially within the housing. For instance, in some examples, the third semiconductor die may also include a Schottky diode (e.g., silicon carbide-based Schottky diode). In such examples, the third semiconductor die may be coupled in parallel with the first semiconductor die. It should be noted that, although described herein as having two semiconductor die and/or three semiconductor die, example power semiconductor device packages of the present disclosure may have any number of semiconductor die without deviating from the scope of the present disclosure.

In some examples, the first semiconductor die and the second semiconductor die may be arranged (e.g., provided on) a submount. For instance, in some examples the first semiconductor die and the second semiconductor die may be arranged on a power substrate, such as a direct bonded copper (DBC) substrate, an active metal brazed (AMB) substrate, and/or the like. As discussed in greater detail below, the power substrate may include a plurality of metal layers and an insulating layer between the metal layers. In some examples, at least a portion of the power substrate may be at least partially exposed through a major side of the housing to provide a heat dissipation path (e.g., cooling path) for the first semiconductor die and the second semiconductor die. Additionally and/or alternatively, in some examples, the first semiconductor die and the second semiconductor die may be arranged on a lead frame. In some examples, at least a portion of the lead frame may be at least partially exposed through a major side of the housing to provide a heat dissipation path (e.g., cooling path) for the first semiconductor die and the second semiconductor die. Additionally and/or alternatively, in some examples, the first semiconductor die and the second semiconductor die may be arranged on a lead frame, and the lead frame may be arranged on a power substrate. In some examples, at least a portion of the power substrate, on which the lead frame is arranged, may be at least partially exposed through a major side of the housing to provide a heat dissipation path (e.g., cooling path) for the first semiconductor die and the second semiconductor die.

The power semiconductor device package of the present disclosure may include a plurality of electrical leads extending from the housing. In some examples, each of the plurality of electrical leads may extend from a same side of the housing relative to one another. In other examples, at least one electrical lead of the plurality of electrical leads may extend from a different side of the housing relative to at least one other electrical lead. Those having ordinary skill in the art, using the disclosures provided herein, will understand that power semiconductor device packages of the present disclosure may include any suitable electrical lead without deviating from the scope of the present disclosure, such as extended lead(s), surface mount type (SMT) connection structure(s), Gull-wing pin(s), and/or the like.

In some examples, at least one electrical lead of the plurality of electrical leads may be coupled to the first semiconductor die, and at least one electrical lead of the plurality of electrical leads may be coupled to the second semiconductor die. More particularly, a first lead of the plurality of electrical leads may be coupled to the first semiconductor die (e.g., coupled to a cathode contact of the first semiconductor die), a second lead of the plurality of electrical leads may be coupled to the first semiconductor die (e.g., coupled to an anode contact of the first semiconductor die) and the second semiconductor die (e.g., coupled to a drain contact of the second semiconductor die), and a third lead of the plurality of electrical leads may be coupled to the second semiconductor die (e.g., coupled to a source contact of the second semiconductor die). In some examples, the plurality of electrical leads of the power semiconductor device package may include more than three leads. For instance, in some examples, the plurality of electrical leads may include a fourth lead and a fifth lead. More particularly, a fourth lead of the plurality of electrical leads may be coupled to the second semiconductor die (e.g., coupled to a source-kelvin contact of the second semiconductor die), and a fifth lead of the plurality of electrical leads may be coupled to the second semiconductor die (e.g., coupled to a gate contact of the second semiconductor die).

Although described herein as including a plurality of electrical leads, those having ordinary skill in the art, using the disclosures provided herein, will understand that power semiconductor device packages of the present disclosure may include any suitable connection structure (e.g., pin, terminal, contact, interconnect, bonding pad, and/or the like) without deviating from the scope of the present disclosure.

In some examples, the power semiconductor device package of the present disclosure may also include a thermal pad. The thermal pad may be arranged on and/or at least partially exposed through a major side of the housing. In this way, the thermal pad may provide for cooling of the power semiconductor device package through one of the major sides of the housing (e.g., top-side cooling, bottom-side cooling, dual-side cooling, etc.). The thermal pad may be electrically isolated from the plurality of electrical leads. In some examples, the thermal pad may be electrically isolated from the first semiconductor die and the second semiconductor die. In some examples, the thermal pad may be coupled to a drain contact of one of the first semiconductor die or the second semiconductor die. More particularly, in some examples, the thermal pad may be coupled to one of the anode contact of the first semiconductor die and/or the drain contact of the second semiconductor die. In some examples, the thermal pad may allow for the attachment of a heat sink (e.g., with an electrical isolator) to enhance thermal performance.

As noted above, the power semiconductor device package of the present disclosure may include one or more creepage extension structures (e.g., creepage cutout(s), creepage feature(s), etc.). As used herein, a “creepage extension structure” refers to any structure operable to provide a power semiconductor device package with increased creepage distance. By providing the power semiconductor device package with increased creepage distance(s), the creepage extension structure(s) may reduce the adverse performance-related effects described above, while also increasing the current and voltage handling capabilities of the power semiconductor device package.

For instance, in some examples, the power semiconductor device package may include one or more creepage cutouts. As used herein, a “creepage cutout” refers to a creepage extension structure that is formed on, and extends across, a minor side of the housing, such as the minor side of the housing from which the plurality of electrical leads extends. Put differently, a “creepage cutout” refers to a creepage extension structure that provides an increased creepage distance between at least two electrical leads of the plurality of electrical leads. By way of non-limiting illustrative example, a power semiconductor device package of the present disclosure may include a creepage cutout between the first lead and the second lead of the plurality of electrical leads. In such examples, the creepage cutout may provide an increased creepage distance (e.g., in a range of about 10 microns to about 15 microns) between the first lead and the second lead. As such, the creepage cutout may effectively increase a surface distance (e.g., creepage distance) along the housing of the power semiconductor device package between the first lead and the second lead, thereby increasing voltage isolation between the first lead and the second lead.

As will be discussed in greater detail below, a creepage cutout of the present disclosure may be any suitable rectangular creepage cutout having one or more sidewall segments and/or any suitable non-rectangular creepage cutout having one or more sidewall segments. For instance, by way of non-limiting example, the creepage cutout may be a circular creepage cutout having at least one sidewall segment, a curved creepage cutout having at least one sidewall segment, a triangular creepage cutout having at least two segments, a square creepage cutout having at least three sidewall segments, a rectangular creepage cutout having at least three sidewall segments, an L-shaped creepage cutout having at least five sidewall segments, a T-shaped creepage cutout having at least seven sidewall segments, a hexagonal creepage cutout having at least seven sidewall segments, a cross-shaped creepage cutout having at least eleven sidewall segments, and/or the like.

Furthermore, in some examples, the power semiconductor device package may further include one or more creepage features in the housing. As used herein, a “creepage feature” refers to a creepage extension structure that is formed on, and extends at least partially across, a major side of the housing. Put differently, a “creepage feature” refers to a creepage extension structure that provides an increased creepage distance between at least one of the plurality of electrical leads and one or more structures arranged on a major side of the housing. By way of non-limiting example, a power semiconductor device package of the present disclosure may include a creepage feature arranged on a major side of the housing between the thermal pad and the plurality of electrical leads (e.g., which extend from the housing in a perpendicular direction relative to the thermal pad). In such examples, the creepage feature may provide an increased creepage distance (e.g., in a range of about 7 microns to about 11 microns) between the thermal pad and the plurality of electrical leads. In some examples, the power semiconductor device package may include a first creepage feature on a major side of the housing and a second creepage feature on an opposing major side of the housing relative to the first creepage feature. As such, the creepage feature may effectively increase a surface distance (e.g., creepage distance) along the housing of the power semiconductor device package between the thermal pad and the plurality of electrical leads, thereby increasing voltage isolation between the thermal pad and the plurality of electrical leads. As will be discussed in greater detail below, a creepage feature of the present disclosure may be any suitable creepage feature. For instance, by way of non-limiting example, the creepage feature may define a step structure in the housing, a trench in the housing, and/or the like.

Aspects of the present disclosure provide a number of technical effects and benefits. For instance, a power semiconductor device package according to the present disclosure may provide efficient thermal dissipation through a thermal pad and may also provide multiple pin-out options for the plurality of electrical leads. Furthermore, a power semiconductor device package having a creepage extension structure according to the present disclosure, such as a creepage cutout and/or a creepage feature, may provide a high voltage rating and/or a high current rating due to the increased creepage distance resulting from the creepage extension structure (e.g., a rated voltage of about 1500 volts). As such, the creepage cutout and creepage feature ensure proper insulation and reduce electrical breakdown in high-voltage semiconductor devices. In this way, example aspects of the present disclosure provide increased current and voltage capabilities for semiconductor packages, such as discrete power semiconductor device packages, thereby providing for increased reliability and longevity of high-voltage semiconductor devices.

Moreover, by including at least two semiconductor die packaged within the same housing that are different respective types of semiconductor devices (e.g., Schottky diodes, MOSFETs, etc.), example aspects of the present disclosure enable various additional switch configurations and provide enhanced flexibility with different pin-out options for the plurality of electrical leads. As such, example aspects of the present disclosure provide a compact and cost-effective power semiconductor device package with a reduced form factor, while simultaneously providing for increased current-and voltage-handling capabilities relative to other semiconductor device packages having similarly small form factors. Furthermore, the packaging technology described herein (and the configuration of the internal components therein) provides an overall reduction in part count and cost, an increased power density, a simplified thermal management assembly, and a reduced parasitic inductance relative to other semiconductor device packages.

It will be understood that, although the terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. Furthermore, a “plurality” is a plural form that, as used herein, is intended to refer to “at least two” and/or “two or more” stated features, integers, steps, operations, elements, components, and/or the like. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present, except in some examples an attach material (e.g., die-attach material, solder, paste, adhesive, sintered material or other material may be present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present, except in some examples an attach material (e.g., die-attach material, solder, paste, adhesive, sintered material or other material may be present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments of the disclosure. The thickness of layers and regions in the drawings may be exaggerated for clarity. Additionally, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to silicon carbide-based semiconductor structures, such as silicon carbide-based MOSFETs. Those of ordinary skill in the art, using the disclosures provided herein, will understand that the power semiconductor packages according to example embodiments of the present disclosure may be used with any semiconductor material, such as other wide band gap semiconductor materials, without deviating from the scope of the present disclosure. Example wide band gap semiconductor materials include silicon carbide (e.g., 2.996 eV band gap for alpha silicon carbide at room temperature) and the Group III-nitrides (e.g., 3.36 eV band gap for gallium nitride at room temperature).

In the drawings and specification, there have been disclosed typical embodiments and, although specific terms are employed, they are used in a generic and descriptive sense only and not for purposes of limitation of the scope set forth in the following claims.

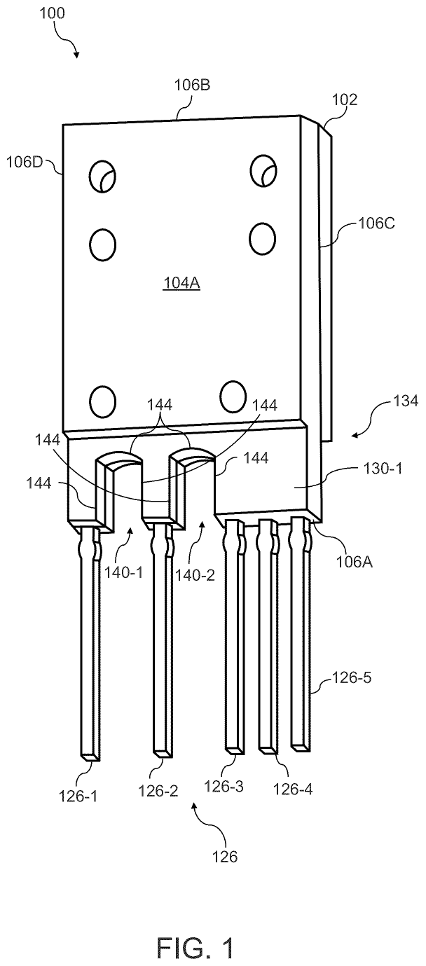

FIG. 1-6 depict an example power semiconductor device package 100 according to example embodiments of the present disclosure. Although the power semiconductor device package 100 is depicted and described herein as a discrete power semiconductor device package, those having ordinary skill in the art, using the disclosures provided herein, will understand that the example aspects described below may also be appliable to other power semiconductor device packages, such as power module, without deviating from the scope of the present disclosure. It should be understood that FIG. 1-6 are intended to represent structures for purposes of identification and description and are not intended to represent the structures to physical scale.

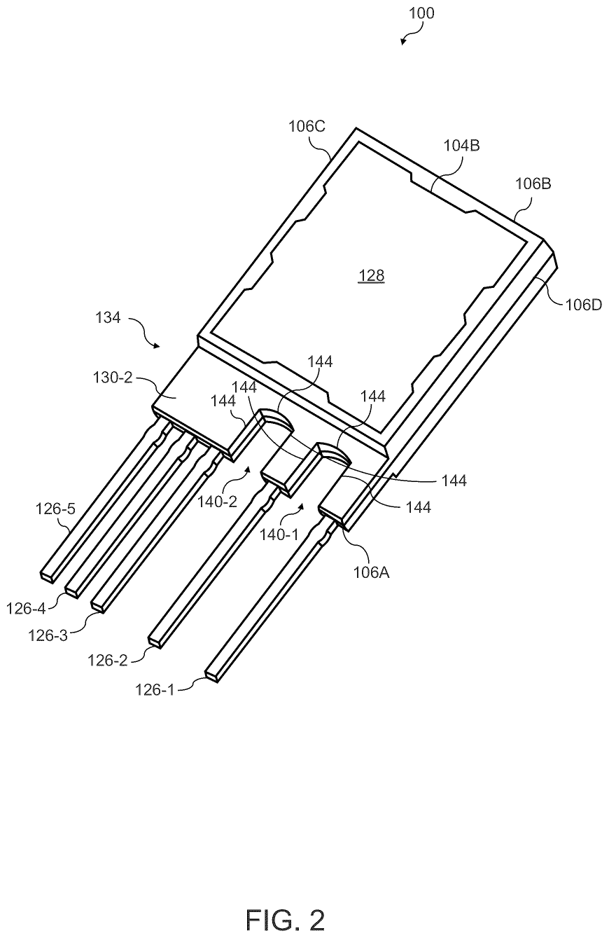

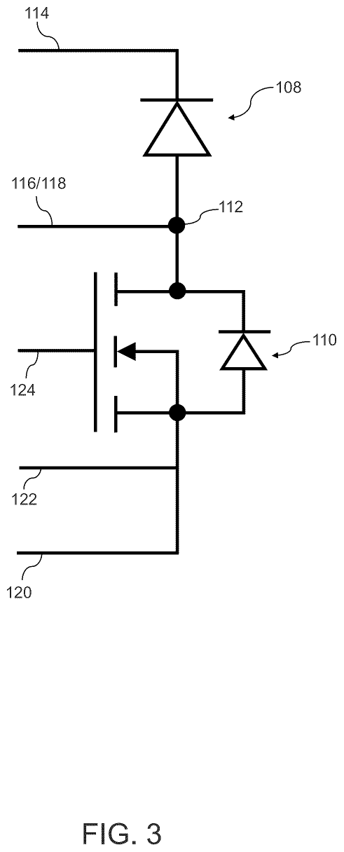

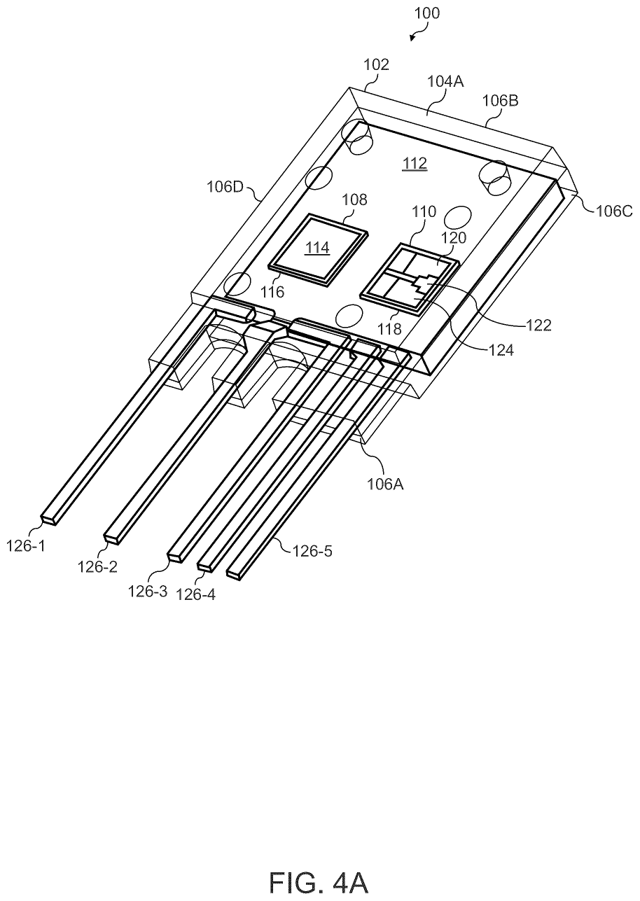

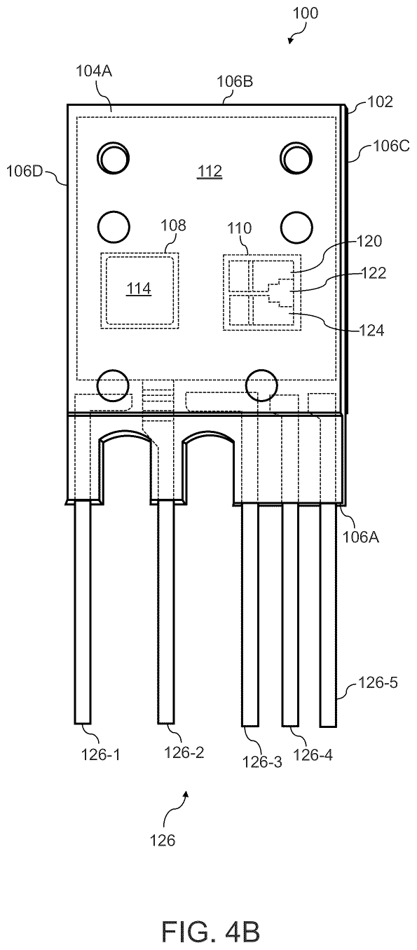

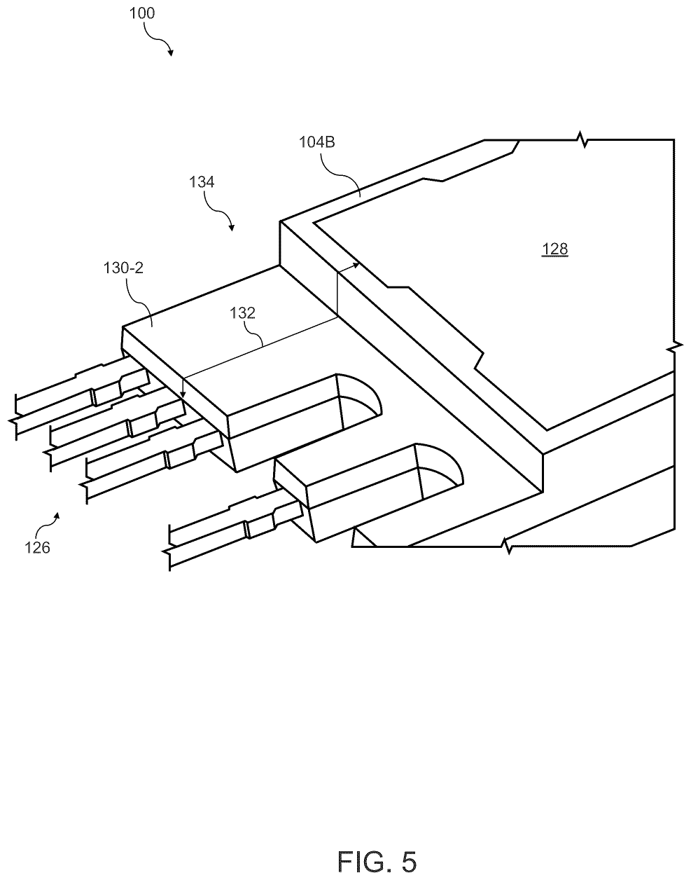

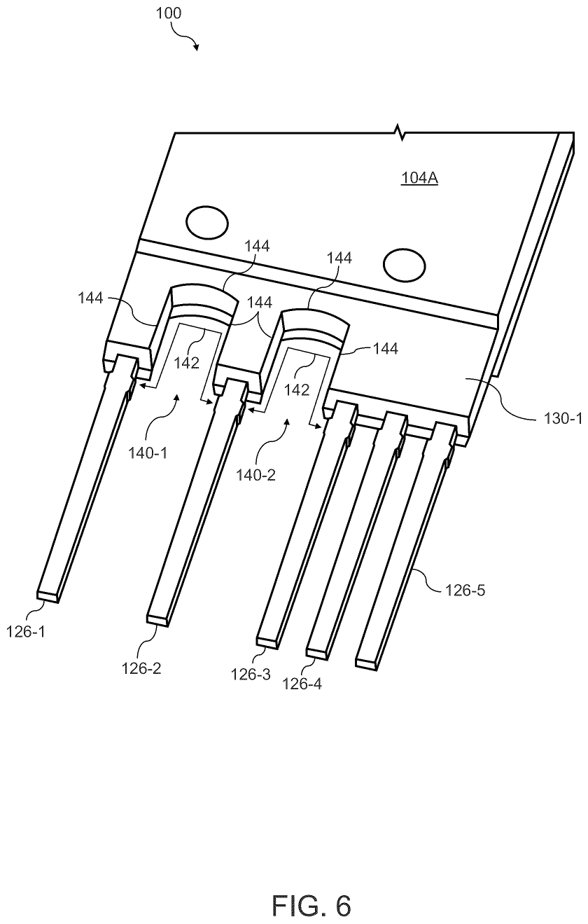

Referring now to FIG. 1-6, FIG. 1 depicts a top perspective view of the power semiconductor device package 100, FIG. 2 depicts a bottom perspective view of the power semiconductor device package 100, FIG. 3 depicts a circuit schematic diagram of the power semiconductor device package 100, FIG. 4A depicts a top perspective wireframe view of the power semiconductor device package 100, FIG. 4B depicts a top wireframe view of the power semiconductor device package 100, FIG. 5 depicts a close perspective view of example creepage features of the power semiconductor device package 100, and FIG. 6 depicts example creepage cutouts of the power semiconductor device package 100.

As shown, the power semiconductor device package 100 includes a housing 102. The housing 102 may be formed by a molding process. The housing 102 may include a material capable of high temperature operation, such as a temperature of about 200° C. In some examples, the housing 102 may be and/or may include an encapsulating material. By way of non-limiting example, the housing 102 may be and/or may include an epoxy material, an epoxy mold compound (EMC), and/or the like. It should be understood that the housing 102 is depicted as transparent in FIG. 4A-4B.

The housing 102 may include one or more surfaces and/or one or more sides. For instance, the housing may include one or more “major” sides 104 and one or more “minor” sides 106. As noted above, a “major side(s)” and/or a “major surface(s)” refers to a primary (e.g., most significant) surface(s) of the housing 102, such as the principal face(s) of the housing 102, the side(s) having the largest surface area, and/or the like. Conversely, a “minor side(s)” and/or a “minor surface(s)” refers to a secondary (e.g., less prominent) surface(s) of the housing 102 relative to the “major side(s),” such as the side surface(s) of the housing 102, the side(s) having a smaller surface area relative to the principal faces, and/or the like. It should be understood that, when describing the housing 102, the terms “surface” and “side” may be used interchangeably.

For instance, as shown, the housing 102 may include a first major side 104A (e.g., front side) (FIG. 1) and a second major side 104B (e.g., back side, rear-side, etc.) (FIG. 2) (collectively, “sides 104”). The second major side 104B may be generally opposite the first major side 104A. The first major side 104A and the second major side 104B are hereinafter referred to as side 104A and side 104B, respectively. As shown in FIG. 1-2, the sides 104 may generally parallel relative to one another and may be the principal faces of the housing 102. The housing 102 may further include one or more minor sides 106 adjacent to and extending between the sides 104.

For instance, as shown, the housing 102 may include a first minor side 106A (e.g., bottom-side surface), a second minor side 106B (e.g., top-side surface), a third minor side 106C (e.g., right-side surface), and a fourth minor side 106D (e.g., left-side surface) (collectively, “sides 106”). The first minor side 106A, the second minor side 106B, the third minor side 106C, and the fourth minor side 106D are hereinafter referred to as side 106A, side 106B, side 106C, and side 106D, respectively. The side 106B may be generally opposite the side 106A; the side 106D may be generally opposite the side 106C. The sides 106 may be generally perpendicular to the sides 104; the sides 106A, 106B may be generally perpendicular to the sides 106C, 106D. The sides 106A, 106B may be generally parallel relative to one another; the sides 106C, 106D may be generally parallel relative to one another.

It should be understood that the housing 102 may include different arrangements of surfaces without deviating from the scope of the present disclosure. For instance, one or more notches and/or one or more recesses may be formed on any of the sides and/or surfaces of the housing 102 without deviating from the scope of the present disclosure.

The power semiconductor device package 100 may be arranged to house and provide external connections to one or more semiconductor die. For instance, referring briefly to FIG. 4A-4B, the power semiconductor device package 100 may include a first semiconductor die 108 and a second semiconductor die 110. As shown, the first semiconductor die 108 and the second semiconductor die 110 may be arranged within the housing 102. It should be understood that the power semiconductor device package 100 is depicted in FIG. 4A-4B as having two semiconductor die (e.g., first semiconductor die 108, second semiconductor die 110) for purposes of illustration and discussion. Those having ordinary skill in the art, using the disclosures provided herein, will understand that example power semiconductor device packages of the present disclosure may have more than two semiconductor die without deviating from the scope of the present disclosure.

Referring still to FIG. 4A-4B, the first semiconductor die 108 and the second semiconductor die 110 may be mounted on a mounting substrate, such as a submount 112 (e.g., conductive lead frame). The first semiconductor die 108 and the second semiconductor die 110 may be respectively coupled to the submount 112 with, for instance, a die-attach material. In some examples, the first semiconductor die 108 and the second semiconductor die 110 may be directly coupled to the submount 112. As will be discussed in greater detail below, in some examples, the submount 112 may be and/or may include a power substrate, such as a direct bonded copper (DBC) substrate, an active metal brazed (AMB) substrate, and/or the like. In some examples, the submount 112 may be and/or may include a lead frame, such as a conductive lead frame and/or the like. In some examples, the submount 112 may be and/or may include a lead frame, and the lead frame may be arranged on a power substrate.

In some examples, the first semiconductor die 108 and the second semiconductor die 110 may include a wide bandgap semiconductor material, such as silicon carbide (SiC), a Group-III nitride (e. g, gallium nitride (GaN)), and/or the like. As shown, the first semiconductor die 108 may be a different type of semiconductor device relative to the second semiconductor die 110. More particularly, the first semiconductor die 108 may include a Schottky diode, such as a silicon carbide-based Schottky diode, and the second semiconductor die 110 may include a metal-oxide-semiconductor field-effect transistor (MOSFET), such as a silicon carbide-based MOSFET. The first semiconductor die 108 may include a cathode contact 114 and an anode contact 116. The cathode contact 114 may be on a top side of the first semiconductor die 108 (e.g., facing side 104A), and the anode contact 116 may be on a back side of the first semiconductor die 108 (e.g., facing side 104B). The second semiconductor die 110 may include a drain contact 118, a source contact 120, an additional contact 122 (e.g., source-kelvin contact, sensor contact, etc.), and a gate contact 124. The drain contact 118 may be on a back side of the second semiconductor die 110 (e.g., facing side 104B); the source contact 120, the additional contact 122, and the gate contact 124 may be on a front side of the second semiconductor die 108 (e.g., facing side 104A).

Referring now to FIG. 1-6, the power semiconductor device package 100 may include a plurality of electrical leads 126 extending from the housing 102, such as side 106A. Each of the plurality of electrical leads 126 may be at least partially encapsulated by the housing 102 such that a portion of each of the plurality of electrical leads 126 is exposed through the side 106A. For instance, as shown, each of the plurality of electrical leads 126 may extend in a generally perpendicular direction from the side 106A of the housing 102. In some examples, each of the plurality of electrical leads 126 may extend from a same side of the housing 102, such as, in the example of power semiconductor device package 100, side 102A. The plurality of electrical leads 126 may have the form of electrical connection pins, such as extended leads. It should be understood that, although depicted herein as extended leads, the plurality of electrical leads 126 may have any suitable electrical connection pin, such as surface mount type (SMT) connection structures, Gull-wing pins, and/or the like. At least one electrical lead of the plurality of electrical leads 126 may be coupled to each of the first semiconductor die 108 and the second semiconductor die 110.

For instance, in the example of the first semiconductor die 108 including a Schottky diode, a first lead 126-1 and a second lead 126-2 of the plurality of electrical leads 126 may be coupled to the first semiconductor die 108. More particularly, the first lead 126-1 may be connected to the cathode contact 114 of the first semiconductor die 108. In some examples, the first lead 126-1 may be connected to the cathode contact 114 using, for instance, one or more wire bonds (not shown). In this way, the first lead 126-1 may be used to connect the cathode of the first semiconductor die 108 to one or more external connections.

The second lead 126-2 may be connected to the anode contact 116 of the first semiconductor die 108. In some examples, the second lead 126-2 may be connected to the anode contact 116 using, for instance, one or more wire bonds (not shown). Furthermore, in the example of the second semiconductor die 110 including a MOSFET, the second lead 126-2 may also be coupled to the drain contact 118 of the second semiconductor die 110. In some examples, the second lead 126-2 may be connected to the drain contact 118 using, for instance, one or more wire bonds (not shown). In this way, the second lead 126-2 may be used to connect the anode of the first semiconductor die 108, and the drain of the second semiconductor die 110, to one or more external connections.

A third lead 126-3, a fourth lead 126-4, and a fifth lead 126-5 of the plurality of electrical leads 126 may also be coupled to the second semiconductor die 110. More particularly, the third lead 126-3 may be connected to the source contact 120 of the second semiconductor die 110. In some examples, the third lead 126-3 may be connected to the source contact 120 using, for instance, one or more wire bonds (not shown). In this way, the third lead 126-3 may be used to connect the source of the second semiconductor die 110 to one or more external connections.

The fourth lead 126-4 may be connected to the additional contact 122 (e.g., source-kelvin contact, sensor contact) of the second semiconductor die 110. In some examples, the fourth lead 126-4 may be connected to the additional contact 122 using, for instance, one or more wire bonds (not shown). In this way, the fourth lead 126-4 may be used to connect the source-kelvin contact, the sensor contact, etc. of the second semiconductor die 110 to one or more external connections.

The fifth lead 126-5 may be connected to the gate contact 124 of the second semiconductor die 110. In some examples, the fifth lead 126-5 may be connected to the gate contact 124 using, for instance, one or more wire bonds (not shown). In this way, the fifth lead 126-5 may be used to connect the gate of the second semiconductor die 110 to one or more external connections.

It should be understood that the arrangement of the leads 126-1-126-5 of the plurality of electrical leads 126 is for purposes of illustration and discussion. Those having ordinary skill in the art, using the disclosures provided herein, will understand that the leads 126-1-126-5 of the plurality of electrical leads 126 may be rearranged, adjusted, etc. without deviating from the scope of the present disclosure.

Furthermore, as shown in FIG. 2, the power semiconductor device package 100 may further include a conductive structure, such as thermal pad 128, on a major side (e.g., side 104B) of the housing 102. In some examples, the thermal pad 128 may be at least partially exposed through the side 104B. The thermal pad 128 may be electrically isolated from the plurality of electrical leads 126. In some examples, the thermal pad 128 may be coupled to the anode contact 116 of the first semiconductor die 108 and the drain contact 118 of the second semiconductor die 110. The thermal pad 128 may include a thermally conductive material, such as a metal, and may be coupled to an external heat sink (e.g., with an electrical isolator) to provide for cooling of the power semiconductor package 100 through the major side (e.g., side 104B). In this way, the thermal pad 128 may be operable to provide a heat dissipation path through the side 104B for the first semiconductor die 108 and the second semiconductor die 110.

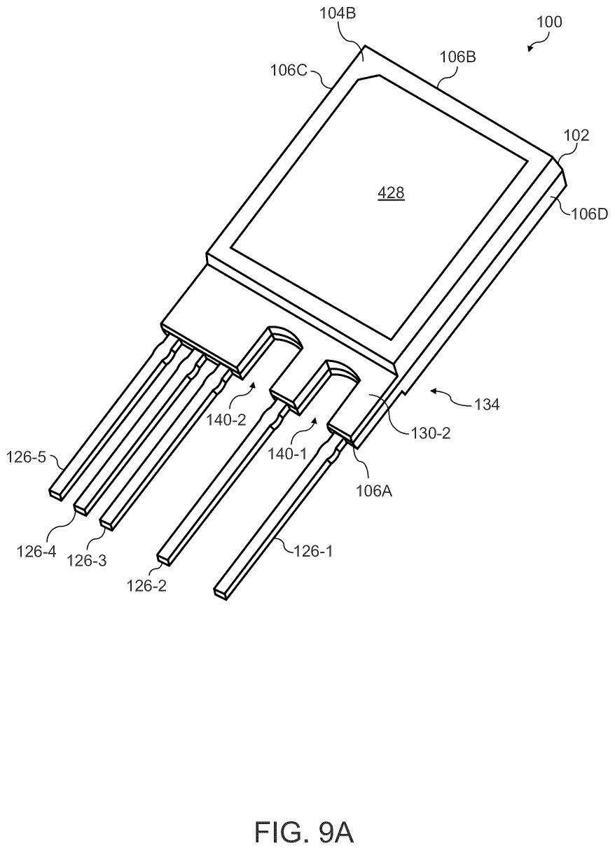

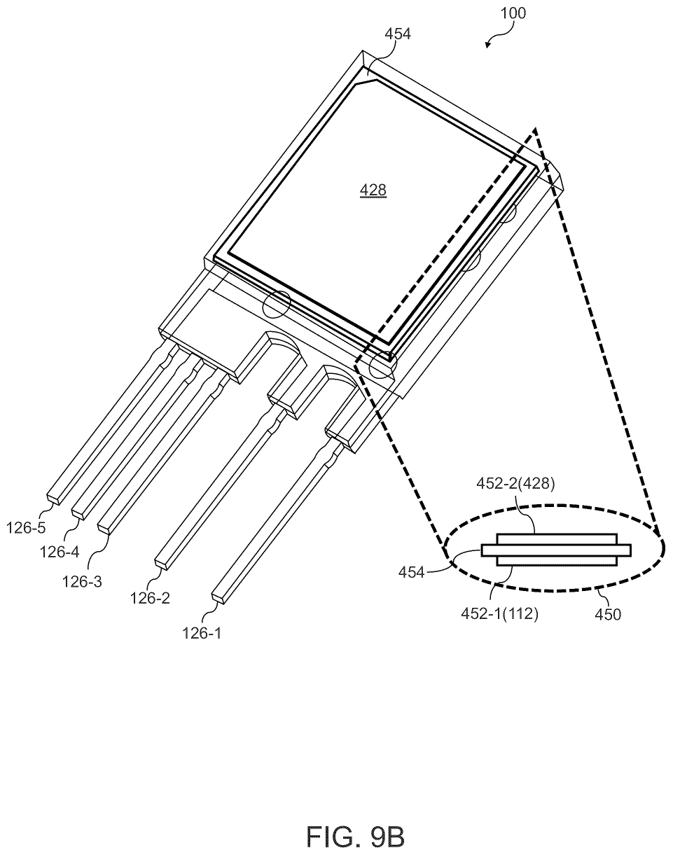

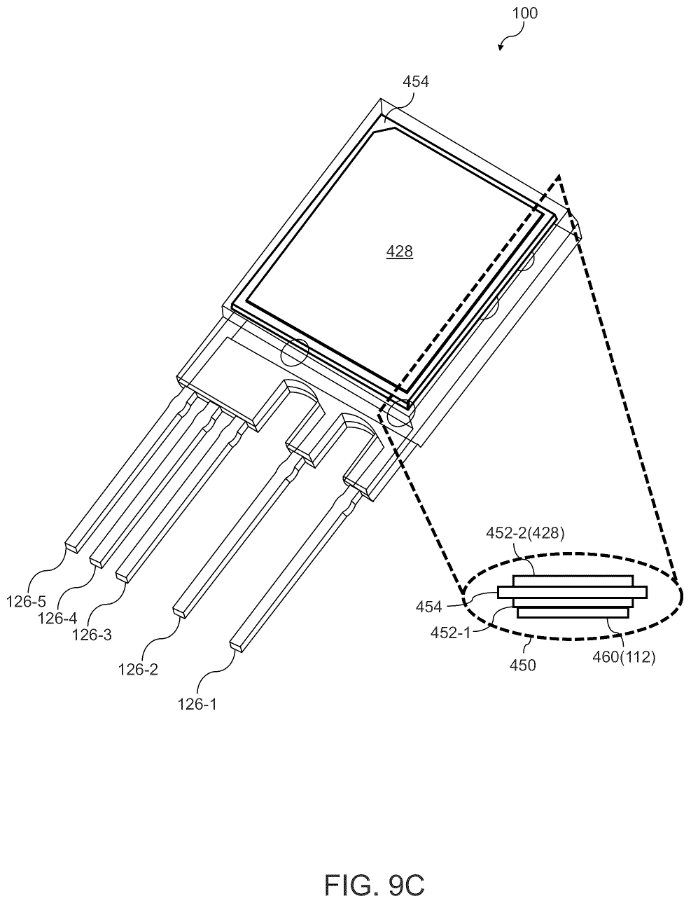

As will be discussed in greater detail below, in some examples, the thermal pad 128 may also be electrically isolated from the first semiconductor die 108 and the second semiconductor die 110 disposed within the housing 102. For instance, as noted above, the first semiconductor die 108 and the second semiconductor die 110, which are disposed within the housing 102, may be mounted on the submount 112 (e.g., mounting substrate) of the power semiconductor device package 100. The submount 112 may be coupled to, or integral with, the thermal pad 128. More particularly, in some examples (e.g., FIG. 9A-9C), the submount 112 may be and/or may form part of a power substrate (e.g., power substrate 450), which includes a plurality of metal layers and an insulating layer between the metal layers. In such examples, the thermal pad 128 may be mounted on the insulating layer of the power substrate. In some examples (e.g., FIG. 9C), the submount 112 may be and/or may form part of a lead frame (e.g., lead frame 460). In this manner, the thermal pad 128 may be electrically isolated from the first semiconductor die 108 and the second semiconductor die 110.

The power semiconductor device package 100 may include one or more creepage extension structures in the housing 102 that are operable to provide the power semiconductor device package 100 with increased creepage distances, such as one or more creepage features 130, one or more creepage cutouts 140, and/or the like. As noted above, a “creepage cutout” refers to a creepage extension structure that is formed on, and extends across, a minor side (e.g., sides 106A-106D) of the housing 102. In this way, creepage cutouts are operable to provide an increased creepage distance between at least two of the plurality of electrical leads 126. Similarly, a “creepage feature” refers to a creepage extension structure that is formed on, and extends at least partially across, a major side (e.g., sides 104A-104B) of the housing 102. In this way, creepage features are operable to provide an increased creepage distance between at least one of the plurality of electrical leads 126 and a conductive structure on a major side of the housing, such as the thermal pad 128.

More particularly, as shown, the power semiconductor device package 100 may include a first creepage feature 130-1 in the housing 102 between the thermal pad 128 and the plurality of electrical leads 126. The first creepage feature 130-1 may be on the side 104A of the housing 102. The power semiconductor device package 100 may further include a second creepage feature 130-2 on an opposing side of the housing 102 relative to the first creepage feature 130-1, such as side 104B. The second creepage feature 130-2 may be in the housing 102 between the thermal pad 128 and the plurality of electrical leads 126.

Referring briefly to FIG. 5, a close perspective view of the second creepage feature 130-2 of the power semiconductor device package 100 is depicted according to example embodiments of the present disclosure. As noted above, creepage (or “creepage distance”) is the shortest direct path along a surface between conductors at different voltage potentials. In the example depicted in FIG. 5, the second creepage feature 130-2 provides a creepage distance 132 (e.g., about 7 microns to about 11 microns) along side 104B of the housing 102. In this manner, the second creepage feature 130-2 increases the shortest direct path (e.g., creepage distance 132) between the thermal pad 128 and the plurality of electrical leads 126. It should be understood that, although not depicted, the first creepage feature 130-1 may likewise provide a similar creepage distance between the thermal pad 128 and the plurality of electrical leads 126 along side 104A of the housing 102.

Referring again to FIG. 1-6, in some examples, the first creepage feature 130-1 and the second creepage feature 130-2 (collectively, “creepage feature 130”) may define a step structure 134 in the housing 102. In some examples, the step structure 134 may have a depth of about 0.5 mm to about 2.0 mm which may, in turn, increase the shortest direct path (e.g., creepage distance 132) along the side 104A (e.g., first creepage feature 130-1) and/or the side 104B (e.g., second creepage feature 130-2) between the thermal pad 128 and the plurality of electrical leads 126. Furthermore, the creepage feature 130 may define a first portion 102′of the housing 102 having a first thickness T₁, and the thermal pad 128 may define a second portion 102″ of the housing 102 having a second thickness T₂; the second thickness T₂ may be larger than the first thickness T₁. As such, the creepage feature 130 may define the step structure 134 in the housing 102. Furthermore, in some examples, the step structure 134 defined by the first creepage feature 130-1 may laterally extend across the entire side 104A (e.g., from side 106C to side 106D). Likewise, the step structure 134 defined by the second creepage feature 130-2 may laterally extend across the entire side 104B (e.g., from side 106C to side 106D). Additionally and/or alternatively, in other examples, the step structure(s) 134 may laterally extend across only a portion of the side 104A (e.g., first creepage feature 130-1) and/or side 104B (e.g., second creepage feature 130-2).

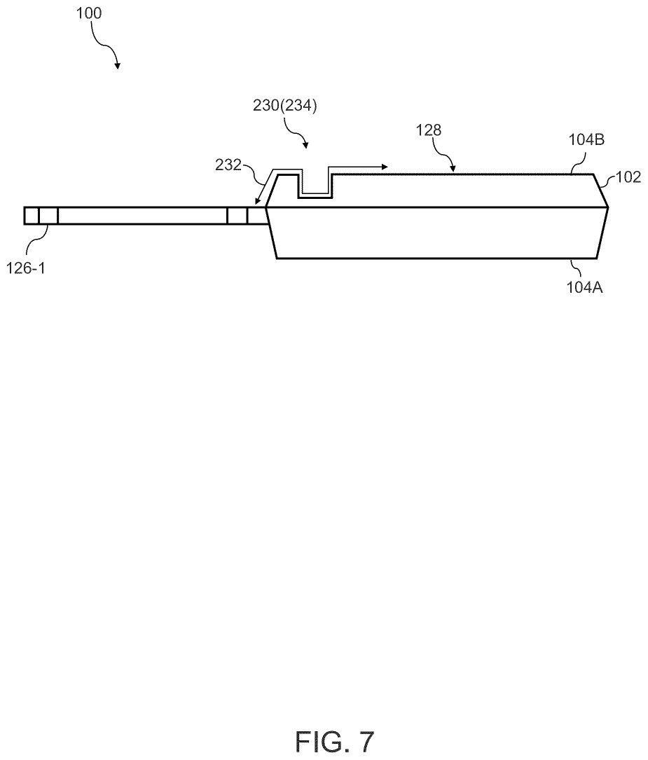

Although depicted as defining the step structure 134 in FIG. 1-6, the creepage feature 130 may, in some examples, define a trench in the housing 102. Creepage feature(s) defining one or more trenches in the housing 102 are discussed in greater detail below with reference to FIG. 7. Furthermore, although depicted as including only two creepage features 130, the power semiconductor device package 100 may include any number of creepage features having any suitable shape without deviating from the scope of the present disclosure.

The power semiconductor device package 100 may further include at least two creepage cutouts 140 in the housing 102 to provide a creepage distance between at least two electrical leads of the plurality of electrical leads 126. More particularly, the power semiconductor device package 100 may include a first creepage cutout 140-1 in the housing 102 between the first lead 126-1 and the second lead 126-2 of the plurality of electrical leads 126. The power semiconductor device package 100 may further include a second creepage cutout 140-2 in the housing 102 between the second lead 126-2 and the third lead 126-3 of the plurality of electrical leads 126. As shown, the first creepage cutout 140-1 may be on side 106A of the housing 102 between the first lead 126-1 and the second lead 126-2, and the second creepage cutout 140-2 may be on side 106A of the housing 102 between the second lead 126-2 and the third lead 126-3.

Referring briefly to FIG. 6, a close perspective view of the first creepage cutout 140-1 and the second creepage cutout 140-2 of the power semiconductor device package 100 is depicted according to example embodiments of the present disclosure. As noted above, creepage (or “creepage distance”) is the shortest direct path along a surface between conductors at different voltage potentials. In the example depicted in FIG. 6, the first creepage cutout 140-1 provides a creepage distance 142-1 (e.g., about 10 microns to about 15 microns) along the side 106A of the housing 102, and the second creepage cutout 140-2 provides a creepage distance 142-2 (e.g., about 10 microns to about 15 microns) along the side 106A of the housing 102. In this manner, the first creepage cutout 140-1 increases the shortest direct path (e.g., creepage distance 142-1) between the first lead 126-1 and the second lead 126-2, and the second creepage cutout 140-2 increases the shortest direct path (e.g., creepage distance 142-2) between the second lead 126-2 and the third lead 126-3.

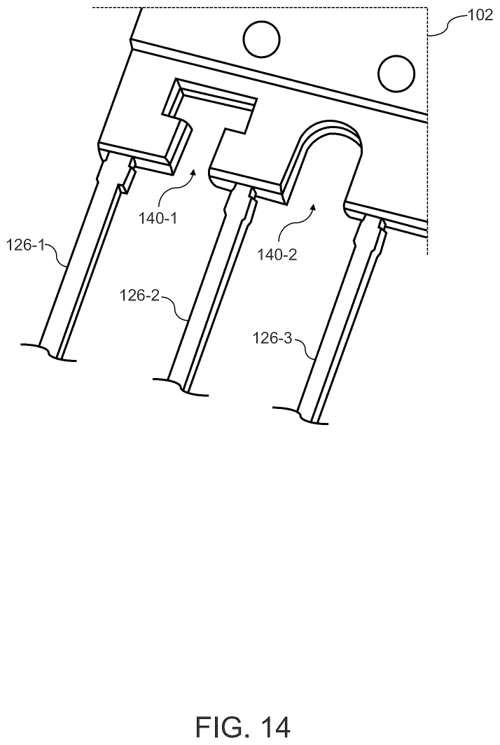

Referring again to FIG. 1-6, the first creepage cutout 140-1 and the second creepage cutout 140-2 may have a same shape relative to one another. Additionally and/or alternatively, in other examples (e.g., FIG. 14), the first creepage cutout 140-1 and the second creepage cutout 140-2 may have a different shape relative to one another. Those having ordinary skill in the art, using the disclosures provided herein, will understand that the creepage cutout(s) of the present disclosure may be any suitable shape without deviating from the scope of the present disclosure.

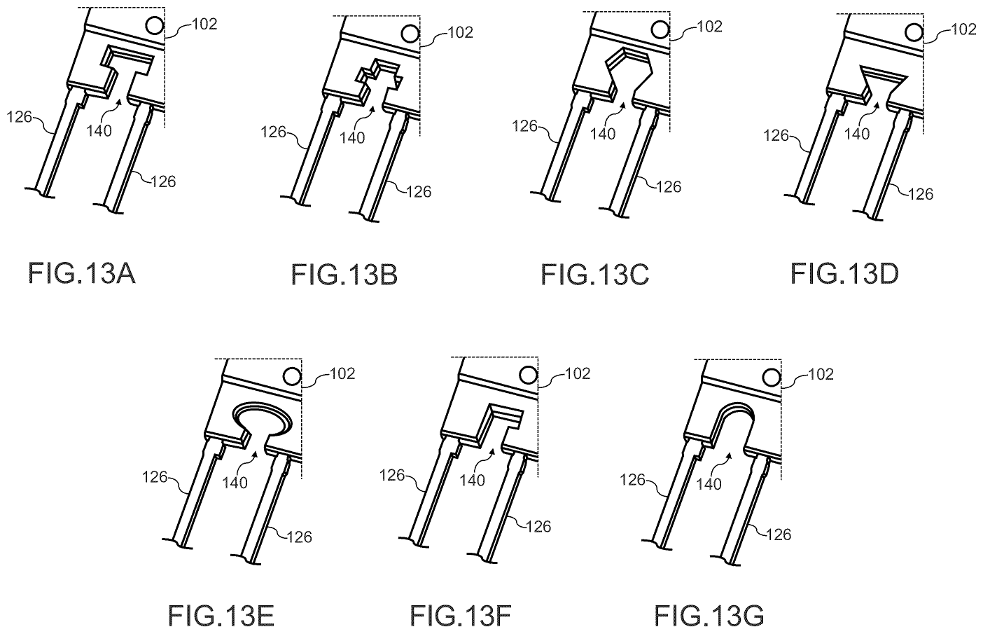

For instance, in the example depicted in FIG. 1-6, the first creepage cutout 140-1 and the second creepage cutout 140-2 may be rectangular creepage cutouts having at least three sidewall segments 144. Although depicted as rectangular creepage cutouts in FIG. 1-6, the first creepage cutout 140-1 and/or the second creepage cutout 140-2 may have any suitable shape without deviating from the scope of the present disclosure. For instance, as discussed in greater detail below, the first creepage cutout 140-1 and/or the second creepage cutout 140-2 may, in some examples, be non-rectangular creepage cutouts, such as, by way of non-limiting example, a T-shaped creepage cutout having at least seven sidewall segments 144 (FIG. 13A), a cross-shaped creepage cutout having at least eleven sidewall segments 144 (FIG. 13B), a hexagonal creepage cutout having at least seven sidewall segments 144 (FIG. 13C), a triangular creepage cutout having at least two sidewall segments 144 (FIG. 13D), a circular creepage cutout having at least one sidewall segment 144 (FIG. 13E), an L-shaped creepage cutout having at least five sidewall segments 144 (FIG. 13F), a curved creepage cutout having at least one sidewall segment 144 (FIG. 13G), and/or the like. Those having ordinary skill in the art, using the disclosures provided herein, will appreciate that the creepage cutout may be any suitable non-rectangular shape having any suitable number of sidewall segments without deviating from the scope of the present disclosure.

Variations and modifications may be made to the example power semiconductor package 100 described herein without deviating from the scope of the present disclosure. For instance, the power semiconductor package 100 may include one or more creepage features 130 defining any suitable structure in the housing 102 operable to provide increased creepage distance between two or more conductors of the power semiconductor package 100 (e.g., thermal pad 128 and the plurality of electrical leads 126), one or more creepage cutouts 140 having any suitable shape and/or number of sidewall segments and operable to provide increased creepage distance between two or more conductors of the power semiconductor package 100 (e.g., at least two of the plurality of electrical leads 126), more than two semiconductor die (e.g., in addition to the first semiconductor die 108 and the second semiconductor die 110) within the housing 102, one or more internal isolation structures (e.g., power substrate(s), lead frame(s), etc.) within the housing 102, one or more structural modifications to the housing 102 (e.g., one or more through holes), and/or any combination thereof.

For instance, FIG. 7 depicts the example power semiconductor device package 100 described above with reference to FIG. 1-6 with a different creepage feature according to example embodiments of the present disclosure. More particularly, FIG. 7 depicts a side plan view of the example power semiconductor device package 100 according to example embodiments of the present disclosure. It should be understood that FIG. 7 is intended to represent structures for purposes of identification and description and is not intended to represent the structures to physical scale.

As shown, the power semiconductor device package 100 includes a creepage feature 230. The creepage feature 230 may be and/or may define a trench 234 in the side 104B of the housing 102. For instance, as shown, the trench 234 may be defined on the side 104B of the housing 102 between the thermal pad 128 and the plurality of electrical leads 126. In some examples, the trench 234 may have a depth D in a range of about 0.25 microns to about 2 microns, such as a depth D in a range of about 0.5 microns to about 1 micron, such as a depth D of about 0.75 microns. In this manner, the creepage feature 230 may increase the shortest direct path (e.g., creepage distance 232) along the side 104B of the housing 102 between the thermal pad 128 the plurality of electrical leads 126. Those having ordinary skill in the art, using the disclosures provided herein, will understand that the creepage features of the present disclosure may have any suitable shape, structure, configuration, etc. without deviating from the scope of the present disclosure, such as any suitable shape, structure, configuration, etc. that serves to increase the shortest direct path along a surface between conductors at different voltage potentials.

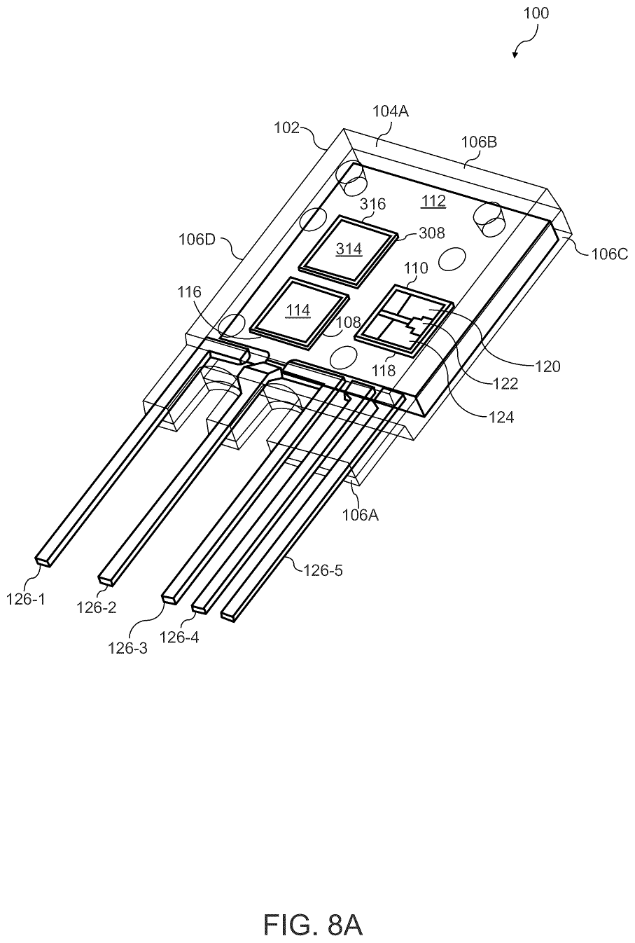

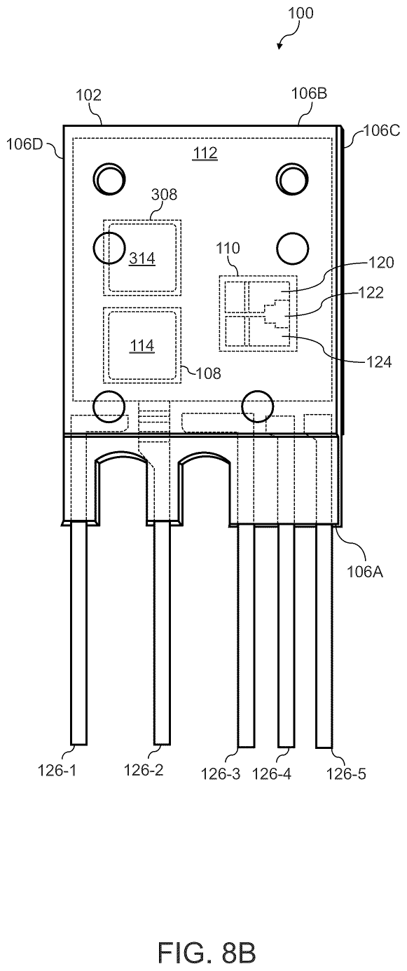

As noted above, in some examples, the power semiconductor device package 100 may include more than two semiconductor die, such as three or more semiconductor die, within the housing 102. For instance, FIG. 8A-8B depict the power semiconductor device package 100 discussed above with reference to FIG. 1-6 with more than two semiconductor die according to example embodiments of the present disclosure. More particularly, FIG. 8A depicts a top perspective wireframe view of the example power semiconductor device package 100, and FIG. 8B depicts a top wireframe view of the example power semiconductor device package 100. It should be understood that the housing 102 is depicted as transparent in FIG. 8A-8B. It should also be understood that FIG. 8A-8B are intended to represent structures for purposes of identification and description and are not intended to represent the structures to physical scale.

As shown in FIG. 8A-8B, in some examples, the power semiconductor device package 100 may include three (or more) semiconductor die. More particularly, as described above, the power semiconductor device package 100 may include the first semiconductor die 108 (e.g., Schottky diode) and the second semiconductor die 110 (e.g., MOSFET), which are mounted on the submount 112 using, e.g., a die-attach material. However, in contrast to FIG. 1-6, the power semiconductor device package 100 depicted in FIG. 8A-8B further includes a third semiconductor die 308. The third semiconductor die 308 may also be mounted on the submount 112. In some examples, the third semiconductor die 308 may be coupled to the submount 112 using, for instance, a die-attach material. In some examples, the third semiconductor die 308 may include a wide bandgap semiconductor material, such as silicon carbide (SiC), a Group-III nitride (e. g, gallium nitride (GaN)), and/or the like. As shown, the third semiconductor die 308 may be a same type of semiconductor device relative to the first semiconductor die 108. However, like the first semiconductor die 108, the third semiconductor die 308 may be a different type of semiconductor device relative to the second semiconductor die 110. More particularly, the third semiconductor die 308 may include a Schottky diode, such as a silicon carbide-based Schottky diode. The third semiconductor die 308 may include a cathode contact 314 and an anode contact 316. The cathode contact 114 may be on a top side of the third semiconductor die 308 (e.g., facing side 104A), and the anode contact 316 may be on a back side of the third semiconductor die 308 (e.g., facing side 104B). In some examples, the third semiconductor die 308 may be coupled in parallel with the first semiconductor die 108 using, for instance, one or more wire bond(s). Those having ordinary skill in the art, using the disclosures provided herein, will understand that example aspects of the present disclosure are not limited to power semiconductor device packages having three semiconductor die, and more than three semiconductor die may be included in example power semiconductor device packages without deviating from the scope of the present disclosure.

It should be understood that, although depicted in FIG. 8A-8B as having rectangular creepage cutouts 140-1, 140-2 in the housing 102, the example power semiconductor device package 100 may have any suitable number of creepage cutouts having any suitable shape and/or combination of shapes without deviating from the scope of the present disclosure. It should be further understood that, although depicted in FIG. 8A-8B as having creepage features 130 that define the step structure 134 in the housing 102, the example power semiconductor device package 100 may have any suitable creepage feature defining any suitable structure, such as creepage feature(s) 230 that define the trench 234 (FIG. 7), without deviating from the scope of the present disclosure.

As noted above, in some examples, the power semiconductor device package 100 may include one or more isolation structures within the housing 102. For instance, FIG. 9A-9C depict the power semiconductor device package 100 discussed above with reference to FIG. 1-6 with one or more isolation structures arranged at least partially within the housing 102 according to example embodiments of the present disclosure. More particularly, FIG. 9A depicts a bottom perspective view of the example power semiconductor device package 100, FIG. 9B depicts a bottom perspective wireframe view of the example power semiconductor device package 100, and FIG. 9C depicts a bottom perspective wireframe view of the example power semiconductor device package 100. It should be understood that the housing 102 is depicted as transparent in FIG. 9B-9C. It should also be understood that FIG. 9A-9C are intended to represent structures for purposes of identification and description and are not intended to represent the structures to physical scale.

Referring now to FIG. 9B, the power semiconductor device package 100 may include an isolated structure 428 that is at least partially exposed through a major side of the housing 102, such as side 104B. The power semiconductor device package 100 may further include a power substrate 450. The power substrate 450 may include a plurality of metal layers 452 and an insulating layer 454 between the metal layers 452. In some examples, the submount 112 may be on and/or may include one of the plurality of metal layers, such as metal layer 452-1. Hence, in some examples, the submount 112 may be on the insulating layer 454 and may be isolated from the isolated structure 428. The insulating layer 454 may be formed from an insulating material, such as a ceramic material and/or other insulating materials.

The insulating layer 454 may have another of the plurality of metal layers 452, such as metal layer 452-2, on a surface opposite the metal layer 452-1 (e.g., opposite the submount 112). In some examples, the isolated structure 428 may be and/or may include one of the plurality of metal layers 452, such as metal layer 452-2. Hence, in some examples, the isolated structure 428 may be on the insulating layer 454. As such, the isolated structure 428 may be isolated from one or more of the submount 112, the first semiconductor die 108 (not shown), the second semiconductor die 110 (not shown), the plurality of electrical leads 126, and/or the like. Furthermore, in some examples, the metal layer 452-2 (e.g., isolated structure 428) may be a thermal pad, such as a thermal pad that is similar to the thermal pad 128 described above with reference to FIG. 1-6. More particularly, as described above, at least a portion of the power substrate 450, such as metal layer 452-2, may be at least partially exposed through the side 104B of the housing 102 to provide a thermally conductive heat dissipation path for the first semiconductor die 108 (not shown) and the second semiconductor die 110 (not shown) through the side 104B of the housing 102. As described herein, in some examples, the submount 112 (e.g., metal layer 652-1) may be electrically coupled to the anode contact 116 of the first semiconductor die 108 and/or the drain contact 120 of the second semiconductor die 110. Put differently, in some examples, the submount 112 (e.g., metal layer 452-1) may likewise be electrically coupled to the second lead 126-2 of the plurality of electrical leads 126. As such, the insulating layer 454 may provide electrical isolation between the metal layer 452-2 (e.g., thermal pad 128, isolated structure 428) and the plurality of electrical leads 126. Furthermore, in some examples, the power substrate 450 may be a direct bonded copper (DBC) substate. Additionally and/or alternatively, in some examples, the power substrate 450 may be an active metal brazed (AMB) substrate.

Referring now to FIG. 9C, in some examples, the first semiconductor die 108 (not shown) and the second semiconductor die 110 (not shown) may be on a conductive structure, such as lead frame 460. In some examples, the submount 112 may include and/or may for part of the lead frame 460. In some examples, such as that depicted in FIG. 9C, the lead frame 460 may be on and/or may be part of the power substrate 450. More particularly, as shown, the lead frame 460 (e.g., second submount 112) may be on metal layer 452-1 of the power substrate 450. As shown, and as described above, at least a portion of the power substrate 450, such as metal layer 452-2 (e.g., isolated structure 428), may be at least partially exposed through the side 104B of the housing 102 to provide a thermally conductive heat dissipation path for the first semiconductor die 108 (not shown) and the second semiconductor die 110 (not shown) through the side 104B of the housing 102.

It should be understood that the arrangement and configuration of the power substrate 450 and/or lead frame 460 as depicted in FIG. 9A-9C is for purposes of illustration and discussion. Those having ordinary skill in the art, using the disclosures provided herein, will understand that the configurations of the example power substrates and/or example lead frames of the present disclosure may be rearranged, adjusted, etc. without deviating from the scope of the present disclosure.

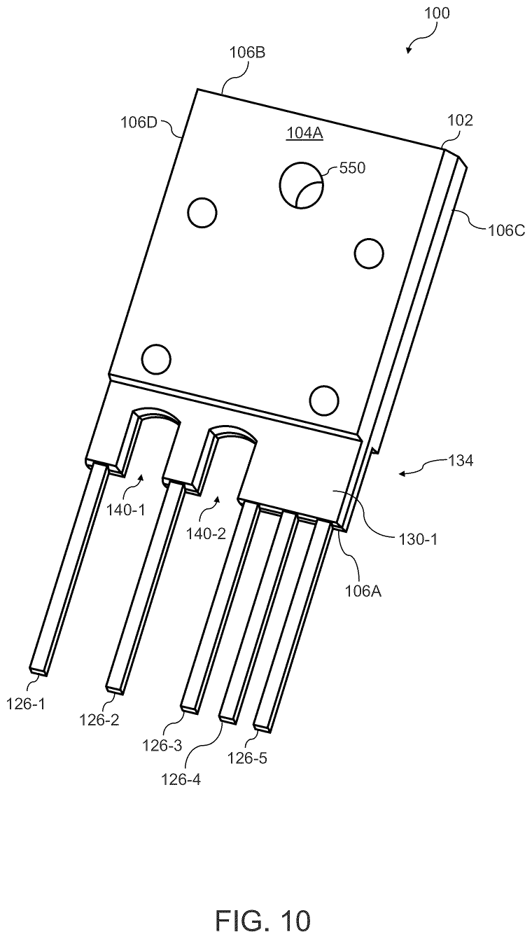

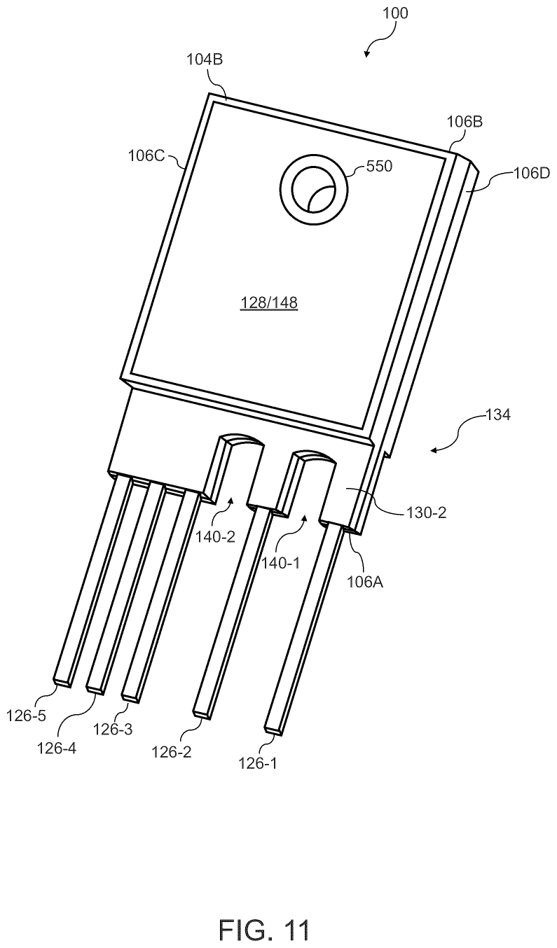

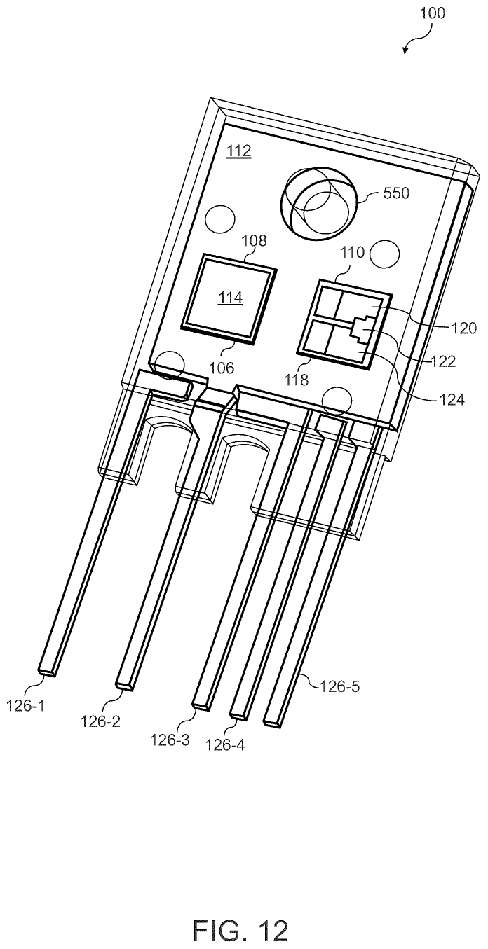

As noted above, in some examples, the power semiconductor device package 100 may include one or more structural modifications to the housing 102. For instance, FIG. 10-12 depict the example power semiconductor device package 100 discussed above with reference to FIG. 1-6 with a through hole 550 in the housing 102 according to example embodiments of the present disclosure. More particularly, FIG. 10 depicts a top perspective view of the example power semiconductor device package 100, FIG. 11 depicts a bottom perspective view of the example power semiconductor device package 100, and FIG. 12 depicts a top perspective wireframe view of the example power semiconductor device package 100. It should be understood that the housing 102 is depicted as transparent in FIG. 12. It should also be understood that FIG. 10-12 are intended to represent structures for purposes of identification and description and are not intended to represent the structures to physical scale.

Referring to FIG. 10-12, as shown, the power semiconductor device package 100 may include the through hole 550. The through hole 550 may extend through the housing 102 from the side 104A to the side 104B. The through hole 550 may be operable to receive a mounting screw (not shown), which allows the power semiconductor device package 100 to be securely fastened to an external device, component, etc. In some examples, the through hole 550 may be a threaded hole, a tapped hole, and/or the like. For instance, the through hole 550 may, in some examples, include internal threading that matches the external threading of the mounting screw, thereby allowing the mounting screw (not shown) to be securely fastened to the power semiconductor device package 100. In some examples, such as that depicted in FIG. 10-12, the through hole 550 may be a circular through hole. In other examples, the through hole 550 may be a non-circular through hole. Those having ordinary skill in the art, using the disclosures provided herein, will understand that the through hole 550 may have any suitable shape and may be operable to receive any suitable fastening device without deviating from the scope of the present disclosure.

As noted above, in some examples, the power semiconductor device package 100 may include one or more creepage cutouts in the housing 102, which may be any suitable shape and/or may have any number of sidewall segments. For instance, by way of non-limiting illustrative example, FIG. 13A-13G depict various example non-rectangular creepage cutouts according to example embodiments of the present disclosure. It should be understood that FIG. 13A-13G are intended to represent structures for purposes of identification and description and are not intended to represent the structures to physical scale.

As noted above, in addition to the other shapes, configurations, and/or arrangements of the creepage cutouts 140 described above (e.g., rectangular creepage cutouts), the first creepage cutout 140-1 and/or the second creepage cutout 140-2 may be non-rectangular creepage cutouts. By way of non-limiting illustrative example, the first creepage cutout 140-1 and/or the second creepage cutout 140-2 may be any of the non-rectangular creepage cutouts depicted in FIG. 13A-13G, such as a T-shaped creepage cutout having at least seven sidewall segments 144 (FIG. 13A), a cross-shaped creepage cutout having at least eleven sidewall segments 144 (FIG. 13B), a hexagonal creepage cutout having at least seven sidewall segments 144 (FIG. 13C), a triangular creepage cutout having at least two sidewall segments 144 (FIG. 13D), a circular creepage cutout having at least one sidewall segment 144 (FIG. 13E), an L-shaped creepage cutout having at least five sidewall segments 144 (FIG. 13F), a curved creepage cutout having at least one sidewall segment 144 (FIG. 13G), and/or the like.

It should be understood that the non-rectangular creepage cutouts depicted in FIG. 13A-13G are for purposes of illustration and discussion. Those having ordinary skill in the art, using the disclosures provided herein, will understand that any suitable rectangular and/or non-rectangular creepage cutout may be used without deviating from the scope of the present disclosure.

As noted above, in some examples, the power semiconductor device package 100 may include a one or more creepage cutouts in the housing 102 that have different shapes relative to one another. For instance, by way of non-limiting illustrative example, FIG. 14 depicts a close perspective view of the example power semiconductor device package 100 having at least two creepage cutouts 140 that have different shapes according to example embodiments of the present disclosure. It should be understood that FIG. 14 is intended to represent structures for purposes of identification and description and is not intended to represent the structures to physical scale.

As shown, in some examples, the power semiconductor device package 100 may include the first creepage cutout 140-1 in the housing 102 between the first lead 126-1 and the second lead 126-2. The first creepage cutout 140-1 may have a first shape. The power semiconductor device package 100 may further include the second creepage cutout 140-2 in the housing 102 between the second lead 126-2 and the third lead 126-3. The second creepage cutout 140-2 may have a second shape. In the examples described above with reference to FIG. 1-6, the first creepage cutout 140-1 and the second creepage cutout 140-2 have the same shape. However, as described herein, the first creepage cutout 140-1 and the second creepage cutout 140-2 may have a different shape relative to one another. As an illustrative example, as shown in FIG. 14, the first creepage cutout 140-1 may be the T-shaped creepage cutout described above with reference to FIG. 13A, and the second creepage cutout 140-2 may be the curved creepage cutout described above with reference to FIG. 13G. Hence, in some examples, the first creepage cutout 140-1 and the second creepage cutout 140-2 may have a different shape relative to one another.

It should be understood that the specific shapes of the creepage cutouts 140 depicted in FIG. 14 are for purposes of illustration and discussion. Those having ordinary skill in the art, using the disclosures provided herein, will understand that power semiconductor device packages of the present disclosure may include any combination of creepage cutouts described herein, such as any of the rectangular creepage cutouts (e.g., FIG. 1- 6) and/or non-rectangular creepage cutouts (e.g., FIG. 13A-13G, without deviating from the scope of the present disclosure.

Example aspects of the present disclosure are set forth below. Any of the below features or examples may be used in combination with any of the embodiments or features provided in the present disclosure.

One example aspect of the present disclosure is directed to a discrete power semiconductor device package. The discrete power semiconductor device package includes a housing. The discrete power semiconductor device package includes a first semiconductor die and a second semiconductor die. The first semiconductor die is a different type of semiconductor device relative to the second semiconductor die. The power semiconductor device package includes a plurality of electrical leads extending from the housing. At least one electrical lead of the plurality of electrical leads is coupled to each of the first semiconductor die and the second semiconductor die.

In some examples, the discrete power semiconductor device package has a rated voltage of about 1500 volts.

In some examples, the first semiconductor die includes a Schottky diode, and the second semiconductor die includes a metal-oxide-semiconductor field-effect transistor (MOSFET).

In some examples, the first semiconductor die and the second semiconductor die are arranged within the housing.

In some examples, the power semiconductor device package further includes a third semiconductor die within the housing.

In some examples, the third semiconductor die is a Schottky diode, and the third semiconductor die is coupled in parallel with the first semiconductor die.

In some examples, a first lead of the plurality of electrical leads is connected to a cathode contact of the first semiconductor die, a second lead of the plurality of electrical leads is connected to an anode contact of the first semiconductor die and a drain contact of the second semiconductor die, and a third lead of the plurality of electrical leads is connected to a source contact of the second semiconductor die.

In some examples, a fourth lead of the plurality of electrical leads is connected to a source-kelvin contact of the second semiconductor die, and a fifth lead of the plurality of electrical leads is connected to a gate contact of the second semiconductor die.

In some examples, the power semiconductor device package further includes a first creepage cutout in the housing, the first creepage cutout providing a creepage distance between the first lead and the second lead of the plurality of electrical leads. In some examples, the power semiconductor device package further includes a second creepage cutout in the housing that is different from the first creepage cutout, the second creepage cutout providing a creepage distance between the second lead and the third lead of the plurality of electrical leads.

In some examples, the power semiconductor device package further includes at least two creepage cutouts in the housing, wherein each of the at least two creepage cutouts provide a creepage distance between at least two electrical leads of the plurality of electrical leads.

In some examples, each creepage cutout provides a creepage distance in a range of about 10 microns to about 15 microns.

In some examples, each of the at least two creepage cutouts have a same shape.

In some examples, each of the at least two creepage cutouts have a different shape.

In some examples, each of the at least two creepage cutouts are rectangular creepage cutouts.

In some examples, each of the at least two creepage cutouts are non-rectangular creepage cutouts.

In some examples, each of the at least two creepage cutouts include one of a T-shaped creepage cutout, a cross-shaped creepage cutout, a hexagonal creepage cutout, a triangular creepage cutout, a circular creepage cutout, an L-shaped creepage cutout, or a curved creepage cutout.

In some examples, the power semiconductor device package further includes a thermal pad that is electrically isolated from the plurality of electrical leads.

In some examples, the thermal pad is electrically isolated from the first semiconductor die and the second semiconductor die.

In some examples, the thermal pad is coupled to a drain contact of one of the first semiconductor die or the second semiconductor die.

In some examples, the power semiconductor device package further includes a creepage feature between the thermal pad and the plurality of electrical leads.

In some examples, the creepage feature provides a creepage distance between the thermal pad and the plurality of electrical leads.

In some examples, the creepage distance is in a range of about 7 microns to about 11 microns.

In some examples, the creepage feature defines one of a step structure or a trench in the housing.

In some examples, the creepage feature is a first creepage feature, and the power semiconductor device package further includes a second creepage feature on an opposing side of the housing relative to the first creepage feature.

In some examples, the first semiconductor die and the second semiconductor die are arranged on a submount.

In some examples, the submount is a power substrate, and the power substrate includes a plurality of metal layers and an insulating layer between the metal layers.

In some examples, the power substrate is one of a direct bonded copper (DBC) substrate or an active metal brazed (AMB) substrate.

In some examples, the submount is a lead frame.

In some examples, the lead frame is arranged on a power substrate, and the power substrate includes a plurality of metal layers and an insulating layer between the metal layers.

In some examples, the housing includes an encapsulating material, and the encapsulating material is formed around at least a portion of the submount.

In some examples, the encapsulating material includes an epoxy mold compound (EMC).

In some examples, each of the plurality of electrical leads extend from a same side of the housing.

In some examples, the power semiconductor device package further includes a through hole in the housing, the through hole extending through the housing from a first major side of the housing to a second major side of the housing.

In some examples, the through hole is operable to receive a mounting screw.

In some examples, the through hole is a circular through hole.

In some examples, the through hole is a non-circular through hole.

In some examples, the first semiconductor die and the second semiconductor die include a wide bandgap semiconductor material, the wide bandgap semiconductor material being one of silicon carbide (SiC) or a Group-III nitride.

Another example aspect of the present disclosure is directed to a power semiconductor device package. The power semiconductor device package includes a housing, a first semiconductor die and a second semiconductor die, a plurality of electrical leads extending from the housing, and at least two creepage cutouts in the housing.

In some examples, the power semiconductor device package has a rated voltage of about 1500 volts.

In some examples, each of the plurality of electrical leads extend from a same side of the housing.

In some examples, at least one electrical lead of the plurality of electrical leads is coupled to each of the first semiconductor die and the second semiconductor die.

In some examples, each creepage cutout includes at least three sidewall segments.

In some examples, each of the at least two creepage cutouts provide a creepage distance between at least two electrical leads of the plurality of electrical leads.

In some examples, each creepage cutout provides a creepage distance in a range of about 10 microns to about 15 microns.

In some examples, each of the at least two creepage cutouts have a same shape.

In some examples, each of the at least two creepage cutouts have a different shape.

In some examples, each of the at least two creepage cutouts are rectangular creepage cutouts.

In some examples, each of the at least two creepage cutouts are non-rectangular creepage cutouts.

In some examples, each of the at least two creepage cutouts include one of a T-shaped creepage cutout, a cross-shaped creepage cutout, a hexagonal creepage cutout, a triangular creepage cutout, a circular creepage cutout, an L-shaped creepage cutout, or a curved creepage cutout.

In some examples, the first semiconductor die includes a Schottky diode, and the second semiconductor die includes a metal-oxide-semiconductor field-effect transistor (MOSFET).

In some examples, the first semiconductor die and the second semiconductor die are arranged within the housing.

In some examples, the power semiconductor device package further includes a third semiconductor die coupled in parallel with the first semiconductor die. In some examples, the third semiconductor die includes a Schottky diode.

In some examples, the plurality of electrical leads includes a first lead connected to a cathode contact of the first semiconductor die, a second lead connected to an anode contact of the first semiconductor die and a drain contact of the second semiconductor die, a third lead connected to a source contact of the second semiconductor die, a fourth lead connected to a source-kelvin contact of the second semiconductor die, and a fifth lead connected to a gate contact of the second semiconductor die.

In some examples, the at least two creepage cutouts include a first creepage cutout in the housing between the first lead and the second lead, the first creepage cutout providing a creepage distance between the first lead and the second lead, and a second creepage cutout in the housing between the second lead and the third lead, the second creepage cutout providing a creepage distance between the second lead and the third lead.

In some examples, the first semiconductor die and the second semiconductor die are arranged on a submount.

In some examples, the submount is one of a lead frame or a power module including a plurality of metal layers and an insulating layer between the metal layers.

In some examples, the housing includes an encapsulating material, the encapsulating material formed around at least a portion of the submount.

In some examples, the encapsulating material includes an epoxy mold compound (EMC).

In some examples, the first semiconductor die and the second semiconductor die include a wide bandgap semiconductor material, the wide bandgap semiconductor material being one of silicon carbide (SiC) or a Group-III nitride.

In some examples, the power semiconductor device package is a discrete power semiconductor device package.

Another examples aspect of the present disclosure is directed to a power semiconductor device package. The power semiconductor device package includes a housing. The power semiconductor device package includes a first semiconductor die in the housing. The first semiconductor die includes a Schottky diode. The power semiconductor device package includes a second semiconductor die in the housing. The second semiconductor die includes a metal-oxide-semiconductor field-effect transistor (MOSFET). The power semiconductor device package includes a plurality of electrical leads extending from the housing. The plurality of electrical leads includes a first lead coupled to a cathode contact of the first semiconductor die, a second lead coupled to an anode contact of the first semiconductor die and a drain contact of the second semiconductor die, and a third lead coupled to a source contact of the second semiconductor die.

In some examples, the power semiconductor device package has a rated voltage of about 1500 volts.

In some examples, each of the plurality of electrical leads extend from a same side of the housing.

In some examples, the power semiconductor device package further includes a first creepage cutout in the housing between the first lead and the second lead, the first creepage cutout providing a creepage distance between the first lead and the second lead. In some examples, the power semiconductor device package further includes a second creepage cutout in the housing between the second lead and the third lead, the second creepage cutout providing a creepage distance between the second lead and the third lead.

In some examples, each of the first creepage cutout and the second creepage cutout provide a creepage distance in a range of about 10 microns to about 15 microns.

In some examples, the first creepage cutout has a same shape as the second creepage cutout.

In some examples, the first creepage cutout has a different shape as the second creepage cutout.

In some examples, the first creepage cutout and the second creepage cutout are rectangular creepage cutouts.

In some examples, the first creepage cutout and the second creepage cutout are non-rectangular creepage cutouts.

In some examples, each of the first creepage cutout and the second creepage cutout include one of a T-shaped creepage cutout, a cross-shaped creepage cutout, a hexagonal creepage cutout, a triangular creepage cutout, a circular creepage cutout, an L-shaped creepage cutout, or a curved creepage cutout.

In some examples, the power semiconductor device package further includes a third semiconductor die in the housing. In some examples, the third semiconductor die includes a Schottky diode.

In some examples, the third semiconductor die is coupled in parallel with the first semiconductor die.

In some examples, the plurality of electrical leads further includes a fourth lead coupled to a source-kelvin contact of the second semiconductor die and a fifth lead coupled to a gate contact of the second semiconductor die.

In some examples, the power semiconductor device package further includes a thermal pad that is electrically isolated from the plurality of electrical leads.

In some examples, the thermal pad is electrically isolated from the first semiconductor die and the second semiconductor die.

In some examples, the power semiconductor device package further includes a creepage feature between the thermal pad and the plurality of electrical leads, the creepage feature providing a creepage distance between the thermal pad and the plurality of electrical leads.

In some examples, the creepage feature defines one of a step structure or a trench in the housing.

In some examples, the first semiconductor die and the second semiconductor die are arranged on a submount.

In some examples, the submount is one of a lead frame or a power module including a plurality of metal layers and an insulating layer between the metal layers.

In some examples, the housing includes an encapsulating material, the encapsulating material formed around at least a portion of the submount.

In some examples, the encapsulating material includes an epoxy mold compound (EMC).

In some examples, the power semiconductor device package further includes a through hole in the housing operable to receive a mounting screw, the through hole extending through the housing from a first major side of the housing to a second major side of the housing that is opposite the first major side.

In some examples, the first semiconductor die and the second semiconductor die include a wide bandgap semiconductor material, the wide bandgap semiconductor material being one of silicon carbide (SiC) or a Group-III nitride.

In some examples, the power semiconductor device package is a discrete power semiconductor device package.

Another example aspect of the present disclosure is directed to a power semiconductor device package. The power semiconductor device package includes a housing. The power semiconductor device package includes a first semiconductor die and a second semiconductor die that is a different type of semiconductor device relative to the first semiconductor die. The power semiconductor device package includes a plurality of electrical leads extending from the housing. The plurality of electrical leads includes a first lead coupled to the first semiconductor die, a second lead coupled to the first semiconductor die and the second semiconductor die, and a third lead coupled to the second semiconductor die. The power semiconductor device package includes a first creepage cutout in the housing. The first creepage cutout is between the first lead and the second lead. The power semiconductor device package includes a second creepage cutout in the housing. The second creepage cutout is between the second lead and the third lead.

Another example aspect of the present disclosure is directed to a power semiconductor device package. The power semiconductor device package includes a housing. The power semiconductor device package includes a first semiconductor die and a second semiconductor die that is different from the first semiconductor die. The power semiconductor device package includes a plurality of electrical leads extending from the housing. The power semiconductor device package includes a thermal pad that is electrically isolated from the plurality of electrical leads. The power semiconductor device package includes a creepage cutout in the housing, the creepage cutout providing a creepage distance between at least two electrical leads of the plurality of electrical leads. The power semiconductor device package includes a creepage feature on the housing, the creepage feature providing a creepage distance between the thermal pad and the plurality of electrical leads.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A discrete power semiconductor device package, comprising:
a housing;
a first semiconductor die and a second semiconductor die, wherein the first semiconductor die is a different type of semiconductor device relative to the second semiconductor die; and
a plurality of electrical leads extending from the housing, at least one electrical lead of the plurality of electrical leads coupled to each of the first semiconductor die and the second semiconductor die.

2. The discrete power semiconductor device package of claim 1, wherein the discrete power semiconductor device package has a rated voltage of about 1500 volts.

3. The discrete power semiconductor device package of claim 1, wherein:
the first semiconductor die comprises a Schottky diode; and
the second semiconductor die comprises a metal-oxide-semiconductor field-effect transistor (MOSFET).

4. The discrete power semiconductor device package of claim 3, wherein the first semiconductor die and the second semiconductor die are arranged within the housing.

5. The discrete power semiconductor device package of claim 3, further comprising a third semiconductor die within the housing.

6. The discrete power semiconductor device package of claim 5, wherein the third semiconductor die is a Schottky diode, the third semiconductor die coupled in parallel with the first semiconductor die.

7. The discrete power semiconductor device package of claim 3, wherein:
a first lead of the plurality of electrical leads is connected to a cathode contact of the first semiconductor die;
a second lead of the plurality of electrical leads is connected to an anode contact of the first semiconductor die and a drain contact of the second semiconductor die; and
a third lead of the plurality of electrical leads is connected to a source contact of the second semiconductor die.

8. The discrete power semiconductor device package of claim 7, wherein:
a fourth lead of the plurality of electrical leads is connected to a source-kelvin contact of the second semiconductor die; and
a fifth lead of the plurality of electrical leads is connected to a gate contact of the second semiconductor die.

9. The discrete power semiconductor device package of claim 7, further comprising:
a first creepage cutout in the housing, the first creepage cutout providing a creepage distance between the first lead and the second lead of the plurality of electrical leads; and
a second creepage cutout in the housing that is different from the first creepage cutout, the second creepage cutout providing a creepage distance between the second lead and the third lead of the plurality of electrical leads.

10. The discrete power semiconductor device package of claim 1, further comprising at least two creepage cutouts in the housing, wherein each of the at least two creepage cutouts provide a creepage distance between at least two electrical leads of the plurality of electrical leads.

11. The discrete power semiconductor device package of claim 10, wherein each creepage cutout provides a creepage distance in a range of about 10 microns to about 15 microns.

12. The discrete power semiconductor device package of claim 10, wherein each of the at least two creepage cutouts comprise one of a T-shaped creepage cutout, a cross-shaped creepage cutout, a hexagonal creepage cutout, a triangular creepage cutout, a circular creepage cutout, an L-shaped creepage cutout, or a curved creepage cutout.

13. The discrete power semiconductor device package of claim 1, wherein the first semiconductor die and the second semiconductor die are arranged on a submount.

14. The discrete power semiconductor device package of claim 13, wherein the submount is a power substrate, the power substrate comprising a plurality of metal layers and an insulating layer between the metal layers.

15. The discrete power semiconductor device package of claim 13, wherein the submount is a lead frame.

16. The discrete power semiconductor device package of claim 15, wherein the lead frame is arranged on a power substrate, the power substrate comprising a plurality of metal layers and an insulating layer between the metal layers.

17. The discrete power semiconductor device package of claim 1, wherein each of the plurality of electrical leads extend from a same side of the housing.

18. The discrete power semiconductor device package of claim 1, wherein the first semiconductor die and the second semiconductor die comprise a wide bandgap semiconductor material, the wide bandgap semiconductor material being one of silicon carbide (SiC) or a Group-III nitride.

19. A power semiconductor device package, comprising:
a housing;
a first semiconductor die and a second semiconductor die;
a plurality of electrical leads extending from the housing; and
at least two creepage cutouts in the housing.

20. A power semiconductor device package, comprising:
a housing;
a first semiconductor die in the housing, the first semiconductor die comprising a Schottky diode;
a second semiconductor die in the housing, the second semiconductor die comprising a metal-oxide-semiconductor field-effect transistor (MOSFET); and
a plurality of electrical leads extending from the housing, the plurality of electrical leads comprising:
a first lead coupled to a cathode contact of the first semiconductor die;
a second lead coupled to an anode contact of the first semiconductor die and a drain contact of the second semiconductor die; and
a third lead coupled to a source contact of the second semiconductor die.
